(19) United States
(12) Patent Application Publication
(10) Pub. No.: US 2025/0014860 A1
(43) Pub. Date: Jan. 9, 2025

(54) ION IMPLANTATION METHOD AND ION IMPLANTER

(71) Applicant: Sumitomo Heavy Industries Ion Technology Co., Ltd., Tokyo (JP)

(72) Inventors: Hiroshi MATSUSHITA, Ehime (JP); Masaki ISHIKAWA, Ehime (JP); Tsuyoshi NAKAJIMA, Ehime (JP); Takanori YAGITA, Ehime (JP)

(21) Appl. No.: 18/890,917

(22) Filed: Sep. 20, 2024

Related U.S. Application Data
(63) Continuation of application No. PCT/JP2023/004753, filed on Feb. 13, 2023.

(30) Foreign Application Priority Data
Mar. 23, 2022 (JP) 2022-047386

(51) Int. Cl. H01J 37/304; H01J 37/30; H01J 37/317; H01J 37/32

(52) U.S. Cl. CPC H01J 37/3045; H01J 37/3007; H01J 37/3171; H01J 37/3244; H01J 2237/0827

(57) ABSTRACT

An ion implantation method includes: acquiring a measured value of a neutron dose rate measured at a predetermined position in an ion implanter when a first ion beam containing a first ion species is transported along a beamline; determining whether the measured value exceeds a predetermined threshold; transporting a second ion beam containing a second ion species having a larger mass number than the first ion species along the beamline when the measured value exceeds the predetermined threshold; and irradiating a wafer with the transported first ion beam after transport of the second ion beam.

### CROSS-REFERENCE TO RELATED APPLICATIONS

This is a bypass continuation of International PCT Application No. PCT/JP2023/004753, filed on Feb. 13, 2023, which claims priority to Japanese Patent Application No. 2022-047386, filed on Mar. 23, 2022, which are incorporated by reference herein in their entirety.

### BACKGROUND

### Technical Field

Certain embodiments of the present invention relate to an ion implantation method and an ion implanter.

### Description of Related Art

In a semiconductor manufacturing process, a process of implanting ions into a semiconductor wafer is implemented as standard to change a semiconductor conductivity, change a semiconductor wafer crystal structure, or the like. A device that is used in this process is generally referred to as an ion implanter. The implantation energy of the ion is determined according to a desired implantation depth of the ion to be implanted in the vicinity of the surface of a wafer. A low-energy ion beam is used for implantation into a shallow region, and a high-energy ion beam is used for implantation into a deep region.

Recently, there is an increasing demand for so-called ultra-high energy ion implantation using an ion beam having an even higher energy than that in the high-energy ion implantation in the related art for implantation into a deeper region. The ions accelerated to ultra-high energy may collide with a member present in a beamline of the ion implanter to cause a nuclear reaction. The nuclear reaction that occurs may generate a radiation such as a neutron ray.

### SUMMARY

According to an embodiment of the present disclosure, there is provided an ion implantation method including: acquiring at least one of a first measured value of a neutron dose rate that is measured at a predetermined position in an ion implanter when a first ion beam containing a first ion species with high energy is transported along a beamline in the ion implanter, and a first estimated value of the neutron dose rate that is estimated at the predetermined position when it is assumed that the first ion beam is transported along the beamline; determining whether or not at least one of the first measured value and the first estimated value exceeds a predetermined threshold; transporting a second ion beam containing a second ion species having a larger mass number than the first ion species along the beamline in a case where at least one of the first measured value and the first estimated value exceeds the predetermined threshold; and irradiating a wafer with the first ion beam transported along the beamline, after transport of the second ion beam.

According to another embodiment of the present invention, there is provided an ion implanter including: a first gas supply source that supplies a source gas of a first ion species; a second gas supply source that supplies a source gas of a second ion species having a larger mass number than the first ion species; an ion source that generates an ion beam containing the first ion species or the second ion species by using the source gas that is supplied from the first gas supply source or the second gas supply source; a beamline unit that is configured to transport the ion beam along a beamline and includes an accelerator that accelerates the ion beam; an implantation processing chamber in which implantation processing of irradiating a wafer with the ion beam transported by the beamline unit is performed; a memory in which a program is stored; and a processor, wherein the processor executes, based on the program, acquiring at least one of a first measured value of a neutron dose rate that is measured at a predetermined position in the ion implanter when a first ion beam containing the first ion species with high energy is transported along the beamline in the ion implanter, and a first estimated value of the neutron dose rate that is estimated at the predetermined position when it is assumed that the first ion beam is transported along the beamline; determining whether or not at least one of the first measured value and the first estimated value exceeds a predetermined threshold; transporting a second ion beam containing the second ion species having a larger mass number than the first ion species along the beamline in a case where at least one of the first measured value and the first estimated value exceeds the predetermined threshold; and irradiating the wafer with the first ion beam transported along the beamline, after transport of the second ion beam.

According to still another embodiment of the present invention, there is provided an ion implantation method including: acquiring a plurality of implantation conditions corresponding to a plurality of lots; determining a processing order of the plurality of lots by using the plurality of implantation conditions; and implanting, in the determined processing order, ions into a plurality of wafers included in each of the plurality of lots according to corresponding implantation conditions, wherein in a case where the acquired plurality of implantation conditions include a first implantation condition for implanting a first ion species with high energy and a second implantation condition for implanting a second ion species having a larger mass number than the first ion species, the processing order is determined such that the first ion species with high energy is implanted into a plurality of wafers included in a lot of the first implantation condition after the second ion species has been implanted into a plurality of wafers included in a lot of the second implantation condition.

### BRIEF DESCRIPTION OF THE DRAWINGS

FIG. 1 is a diagram schematically showing a neutron ray scattering member provided in a casing.

FIG. 2 is a sectional view schematically showing a structure of an accommodation portion.

FIG. 3 is a diagram schematically showing a neutron ray scattering member provided separately from the casing.

FIG. 4 is a top view showing a schematic configuration of an ion implanter according to an embodiment.

FIGS. 5A to 5C are side views showing a schematic configuration of the ion implanter of FIG. 4.

FIG. 6 is a top view schematically showing a structure of a front door of a load port.

FIGS. 7A and 7B are top views schematically showing the front doors in an open state of the load port.

FIG. 8 is a flowchart showing a flow of an ion implantation process according to the embodiment.

FIG. 9 is a diagram schematically showing the ion implanter in a first process.

FIG. 10 is a diagram schematically showing the ion implanter in a second process.

FIG. 11 is a diagram schematically showing the ion implanter in a third process.

FIG. 12 is a diagram schematically showing the ion implanter in a fourth process.

FIG. 13 is a diagram schematically showing the ion implanter in a fifth process.

FIG. 14 is a diagram schematically showing the ion implanter in a sixth process.

FIG. 15 is a diagram schematically showing a configuration of a central control device.

FIG. 16 is a block diagram schematically showing a functional configuration of the central control device.

FIGS. 17A and 17B are diagrams schematically showing a driving device that changes the position of a portion into which an ion beam is at least partially incident.

FIGS. 18A and 18B are diagrams schematically showing a deflection device that deflects the ion beam.

FIG. 19 is a graph schematically showing a method for estimating a neutron dose rate.

FIG. 20 is a flowchart showing an example of a method for monitoring a neutron ray according to the embodiment.

FIG. 21 is a flowchart showing another example of the method for monitoring a neutron ray according to the embodiment.

FIG. 22 is a flowchart showing an example of an ion implantation method according to the embodiment.

FIG. 23 is a flowchart showing another example of the ion implantation method according to the embodiment.

### DETAILED DESCRIPTION

When elements capable of causing a nuclear reaction are accumulated in a portion that is irradiated with an ion beam due to the operation of an ion implanter, a dose rate of a neutron ray that is generated when a high-energy ion beam is incident into the portion increases. In a case where the neutron dose rate reaches a management upper limit value, it is necessary to perform maintenance of the ion implanter, such as replacing a component including the portion where the neutron ray is generated, or to removing the component and cleaning the component outside the device. In a case where maintenance of the ion implanter is performed for replacement of a component or cleaning of a component outside the device, the operation of the ion implanter has to be stopped for a certain period of time, which leads to a decrease in productivity of the ion implanter.

It is desirable to provide a technique for suppressing an increase in neutron dose rate.

Any combination of the above-described components or a replacement of the components and expressions of the present disclosure between methods, devices, systems, and the like is also effective as an aspect of the present disclosure.

According to a non-limiting exemplary embodiment of the present invention, it is possible to provide a technique for suppressing an increase in neutron dose rate.

Hereinafter, a mode for carrying out a method, an ion implantation method, and an ion implanter according to the present disclosure will be described in detail with reference to the drawings. In the description of the drawings, the same reference numerals will be assigned to the same elements, and duplicate description will be omitted as appropriate. Further, the configuration which is described below is exemplification and does not limit the scope of the present invention.

The present embodiment relates to an ion implanter for high energy. The ion implanter accelerates an ion beam generated in an ion source, transports a high-energy ion beam obtained by acceleration to a workpiece (for example, a substrate or a wafer W) along a beamline, and implants ions into the workpiece.

The “high energy” in the present embodiment refers to energy of 4 MeV or higher, 5 MeV or higher, or 10 MeV or higher. According to the high-energy ion implantation, desired dopant ions are implanted into the wafer surface with higher energy than in the ion implantation with the energy of lower than 4 MeV in the related art. Therefore, desired impurities can be implanted into a deeper region (for example, a region of a depth of 5 μm or more) of the wafer surface. An application of the high-energy ion implantation is, for example, to form a P-type region and/or an N-type region in the manufacture of a semiconductor device such as a latest image sensor.

In the ion implanter for high energy, a neutron ray can be generated by collision of the high-energy ion beam with a beamline constituent member. According to the findings of the inventors of the present invention, it is found that a neutron ray is generated in a case of using a boron ion beam having energy of 4 MeV or higher. Specifically, nuclear reactions shown by the following (1) and (2) can occur in boron 11B which is a non-radioactive nuclide.

¹¹B+¹¹B→²¹Ne+n (1)

¹¹B+¹²C→²²Ne+n (2)

The above (1) is a nuclear reaction (also referred to as a B-B reaction) in which boron ¹¹B and boron ¹¹B collide with each other to generate a neutron n. First, when a boron ¹¹B ion beam is incident into (collides with) the constituent member of the beamline, the boron ¹¹B is accumulated inside the constituent member. Thereafter, when the ion beam of high-energy boron ¹¹B collides with the boron ¹¹B accumulated inside the constituent member, the B-B reaction shown by the above (1) occurs and a neutron ray is generated.

The above (2) is a nuclear reaction (also referred to as a B-C reaction) in which boron ¹¹B and carbon ¹²C collide with each other to generate a neutron n. Since at least a part of the constituent members of the beamline is made of graphite (that is, carbon), the B-C reaction shown by the above (2) occurs due to the collision of the high-energy boron ¹¹B ion beam with the graphite, and a neutron ray is generated. In addition, the boron ¹¹B is accumulated inside the graphite, so that the neutron ray due to the B-B reaction of the above (1) can also be generated.

In this manner, in the ion implanter for high energy, even though the implantation ions do not include a radioactive nuclide, the high-energy ion beam collides with various locations of the beamline, so that a radioactive nuclide can be generated and a neutron ray can be generated. Therefore, the ion implanter for high energy includes a neutron ray generation source from which a neutron ray can be generated due to collision of the high-energy ion beam. Therefore, in the ion implanter for high energy, it is necessary to appropriately manage the neutron ray that is generated in the neutron ray generation source.

In general, in a case of handling a device that generates a radiation such as a neutron ray, an operation method is considered in which a dedicated radiation management area is provided and an ion implanter is installed in the area. However, it is not easy to separately provide a radiation management area in a semiconductor manufacturing factory for mass production. In the semiconductor manufacturing factory, it is necessary to transport a wafer container or the like at any time between the ion implanter and another device, and in a case where the ion implanter is installed in the radiation management area, carrying-in and out of the wafer container or the like is performed between the ion implanter and the radiation management area. In order to appropriately shield the neutron ray, for example, a concrete wall having a thickness of several tens of cm or more is required, and a shielding door for the carrying-in and out of the wafer container also has a very large thickness. In this case, it is necessary to open and close the thick shielding door each time the wafer container is carried in and out, which requires a great deal of labor. In addition, when the operation of the ion implanter is required to be stopped at the time of opening and closing the shielding door, the production efficiency of the semiconductor device is lowered. Therefore, the inventors have considered mounting a neutron ray scattering member on a casing surrounding an outer periphery of a device main body configuring a beamline, so that a neutron dose rate outside the casing falls below a reference value determined by a law or the like.

As an example of the radiation that is generated in the ion implanter for high energy, an X-ray can be given in addition to the neutron ray described above. A lead plate or the like is mounted on the casing as a shielding member for X-rays. The X-ray is easier to be shielded than the neutron ray, and for example, the X-ray directed to the outside of the casing can be sufficiently shielded by using a lead plate having a thickness in a range of about 1 mm to 5 mm. On the other hand, it is not easy to reduce the neutron dose rate. For example, in a case where a general high-density polyethylene (specific gravity: about 0.95 g/cm³) is used as a neutron ray scattering member, a thickness in a range of about 150 mm to 200 mm is required in order to attenuate the neutron dose rate to 1/10.

In order to reduce the neutron dose rate, it may be desirable to surround the entire device with a neutron ray scattering member having a large thickness. However, in the ion implanter for high energy, since an accelerator for accelerating the ion beam to high energy becomes large, an area occupied by a device main body becomes, for example, 10 m×20 m or more, and a height of the device main body exceeds 2 m. Therefore, when a neutron ray scattering member having a large thickness is mounted on the entire device, a large amount of the neutron ray scattering members is required, which is not desirable because it leads to a significant increase in cost and product weight.

In the present embodiment, complete shielding of a neutron ray is not aimed, and the neutron ray scattering member is intensively disposed at a location where there is a concern that the neutron dose rate may exceed a predetermined reference value determined by a law or the like outside the casing. Specifically, the disposition of the neutron ray scattering member is changed according to a distance from the neutron ray generation source to the casing. The neutron dose rate is inversely proportional to the square of the distance from the neutron ray generation source, and the neutron dose rate increases at a place where the distance from the neutron ray generation source to the casing is short. However, the neutron dose rate decreases at a place where the distance from the neutron ray generation source to the casing is long.

The neutron dose rate that is generated in the neutron ray generation source in the present embodiment is not so large, and for example, the neutron dose rate at a distance of about 1 m from the neutron ray generation source is in a range of about 0.1 to 2 μSv/h. Therefore, the neutron ray scattering member is intensively disposed at a location where the neutron dose rate is relatively high, so that it becomes possible to suppress the neutron dose rate outside the casing to a value equal to or lower than a reference value determined by a law or the like.

The “neutron ray scattering member” in the present embodiment refers to a material having a large scattering effect for a neutron ray. Hydrogen (H) and boron (B) are known as elements having a large scattering effect for a neutron ray, and a material having a high content of hydrogen or boron is preferable as the neutron ray scattering member. For example, as the material having a high hydrogen content, polyolefin such as polyethylene or paraffin can be given as an example, and a material having a hydrogen atom content in a range of 0.08 to 0.15 g/cm³ is preferable. As a specific example, high-density polyethylene having a specific gravity in a range of about 0.94 to 0.97 g/cm³ can be given. Further, as the neutron ray scattering member, a neutron ray scattering member in which a boron compound such as boron oxide (B₂O₃) is contained in high-density polyethylene in an amount in a range of about 10 to 40% by weight may be used.

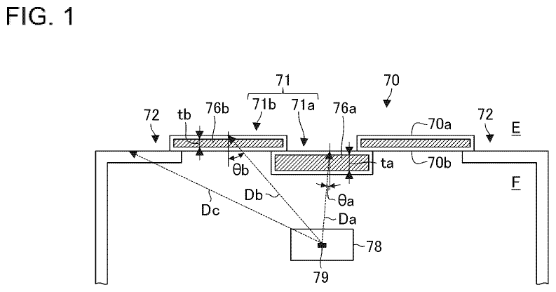

FIG. 1 is a diagram schematically showing neutron ray scattering members 76a and 76b which are provided in a casing 70. The casing 70 is disposed so as to surround the outer periphery of a device 78 that configures the beamline, and separates an external space E and an internal space F. A neutron ray generation source 79 is located inside the device 78. The casing 70 has an outer surface 70a exposed to the external space E and an inner surface 70b exposed to the internal space F. The neutron ray scattering members 76a and 76b are provided inside the casing 70, that is, between the outer surface 70a and the inner surface 70b of the casing 70.

The casing 70 has an accommodation portion 71 (simply referred to as an accommodation portion) provided with the neutron ray scattering members 76a and 76b, and a non-accommodation portion 72 in which a neutron ray scattering member is not provided. The accommodation portion 71 includes a first accommodation portion 71a provided with the first neutron ray scattering member 76a having a relatively large thickness ta, and a second accommodation portion 71b provided with the second neutron ray scattering member 76b having a relatively small thickness tb.

The first neutron ray scattering member 76a is disposed in a first direction (arrow Da) in which a distance from the neutron ray generation source 79 to the outer surface 70a of the casing 70 is a first distance, and is disposed at a position into which the neutron ray that is outgone in the first direction from the neutron ray generation source 79 can be incident. The second neutron ray scattering member 76b is disposed in a second direction (arrow Db) in which a distance from the neutron ray generation source 79 to the outer surface 70a of the casing 70 is a second distance larger than the first distance, and is disposed at a position into which the neutron ray that is outgone in the second direction from the neutron ray generation source 79 can be incident. The thickness ta of the first neutron ray scattering member 76a is, for example, 100 mm or more, and is in a range of about 200 mm to 500 mm. On the other hand, the thickness tb of the second neutron ray scattering member 76b is, for example, 50 mm or more, and is in a range of about 100 mm to 200 mm. The first distance (Da) is, for example, less than 2 m, less than 1.5 m, or less than 1 m, and the second distance (Db) is, for example, less than 10 m, or less than 5 m, and is 2 m or more, 1.5 m or more, or 1 m or more.

A neutron ray scattering member is not disposed in a third direction (arrow Dc) in which a distance from the neutron ray generation source 79 to the outer surface 70a of the casing 70 is a third distance larger than the first distance and the second distance. The third distance (Dc) is, for example, 5 m or more, 10 m or more, or 15 m or more. Therefore, in the present embodiment, the neutron ray scattering member is disposed in a direction in which the distance from the neutron ray generation source 79 to the outer surface 70a of the casing 70 is equal to or shorter than a predetermined value (for example, the second distance), and the neutron ray scattering member is not disposed in a direction in which the distance from the neutron ray generation source 79 to the outer surface 70a of the casing 70 exceeds another predetermined value (for example, the third distance).

It can also be said that the first neutron ray scattering member 76a is disposed at a place where an angle difference θa between the thickness direction of the scattering member and the first direction (arrow Da) from the neutron ray generation source 79 toward the outer surface 70a of the casing 70 is small. On the other hand, it can also be said that the second neutron ray scattering member 76b is disposed at a place where an angle difference Ob between the thickness direction of the scattering member and the second direction (arrow Db) from the neutron ray generation source 79 toward the outer surface 70a of the casing 70 is large. Since the neutron ray from the neutron ray generation source 79 toward the first neutron ray scattering member 76a can be incident into the first neutron ray scattering member 76a at a substantially right angle, an effective thickness (ta/cos(θa)) through which the neutron ray passes and the actual thickness ta of the scattering member are substantially equal to each other. On the other hand, since the neutron ray from the neutron ray generation source 79 toward the second neutron ray scattering member 76b can be obliquely incident into the second neutron ray scattering member 76b, an effective thickness (tb/cos(θb)) through which the neutron ray passes is larger than the actual thickness tb of the scattering member. Therefore, even when the second neutron ray scattering member 76b having a relatively small thickness tb is used, the neutron dose rate in the external space E of the casing 70 can be effectively reduced.

In the example of FIG. 1, the first accommodation portion 71a and the second accommodation portion 71b are disposed adjacent to each other, and the first accommodation portion 71a and the second accommodation portion 71b are disposed so as to at least partially overlap each other in the thickness direction or in a direction from the neutron ray generation source 79 toward the outer surface 70a. In addition, the first neutron ray scattering member 76a provided in the first accommodation portion 71a and the second neutron ray scattering member 76b provided in the second accommodation portion 71b are disposed so as to at least partially overlap each other in the thickness direction or in a direction from the neutron ray generation source 79 toward the outer surface 70a. In this way, it is possible to prevent the neutron ray having a high dose rate from leaking to the external space E through the gap between the first accommodation portion 71a and the second accommodation portion 71b.

In the example of FIG. 1, the thicknesses of the neutron ray scattering members 76a and 76b are changed in two stages. However, the thickness of the neutron ray scattering member may be changed in three or more stages, or the thickness of the neutron ray scattering member may be continuously changed. In addition, in the first accommodation portion 71a and the second accommodation portion 71b, a plate-shaped or block-shaped neutron ray scattering member having a desired thickness ta or tb may be used, or a plurality of plate-shaped or block-shaped neutron ray scattering members each having a thickness thinner than the desired thickness ta or tb may be used to overlap each other in a thickness direction.

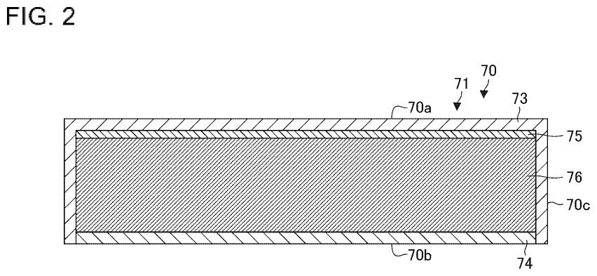

FIG. 2 is a diagram showing in detail a structure of the accommodation portion 71. The accommodation portion 71 has a main body frame 73 and a lid plate 74. An X-ray shielding member 75 and a neutron ray scattering member 76 are provided inside the accommodation portion 71. The main body frame 73 is a support structure for supporting the X-ray shielding member 75 and the neutron ray scattering member 76, and configures the outer surface 70a and a side surface 70c of the accommodation portion 71. The lid plate 74 is mounted in the opening of the main body frame 73, and configures the inner surface 70b of the accommodation portion 71. The main body frame 73 and the lid plate 74 are made of a metal material such as iron or aluminum. The X-ray shielding member 75 and the neutron ray scattering member 76 are disposed to overlap each other in the thickness direction, and are disposed such that, for example, the X-ray shielding member 75 is disposed on the outer surface 70a side and the neutron ray scattering member 76 is disposed on the inner surface 70b side. The X-ray shielding member 75 is, for example, a lead plate, and the neutron ray scattering member 76 is, for example, a plate-shaped or block-shaped high-density polyethylene. Instead of providing the lid plate 74, a non-combustible sheet may be mounted on the surface on the inner surface 70b side of the neutron ray scattering member 76. In addition, a non-combustible sheet may be additionally mounted between the lid plate 74 and the neutron ray scattering member 76. The non-combustible sheet is a sheet-shaped member that does not burn for a certain time (for example, 20 minutes) in a case of being heated, and a polyvinyl chloride (PVC)-based resin sheet, a resin sheet having a glass fiber as a base material, a metal sheet, or the like can be given as an example.

The non-accommodation portion 72 can be configured in the same manner as the accommodation portion 71 except that the neutron ray scattering member 76 is not provided inside the non-accommodation portion 72. For example, the non-accommodation portion 72 includes the main body frame 73 and the lid plate 74 shown in FIG. 2, and the X-ray shielding member 75 is provided inside the non-accommodation portion 72. The thickness of the non-accommodation portion 72 may be the same as the thickness of the accommodation portion 71, or may be smaller than the thickness of the accommodation portion 71. The inside of the non-accommodation portion 72 may be a cavity.

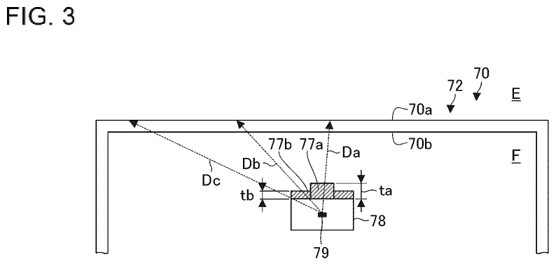

FIG. 3 is a diagram schematically showing neutron ray scattering members 77a and 77b provided separately from the casing 70, and the neutron ray scattering members 77a and 77b are mounted on the device 78 in which the neutron ray generation source 79 is present, or on a support structure of the device 78. Since the casing 70 is not provided with the neutron ray scattering member, the casing 70 is configured as the non-accommodation portion 72 described above. A non-combustible sheet may be mounted on the surface of each of the neutron ray scattering members 77a and 77b.

Also in FIG. 3, the neutron ray scattering members 77a and 77b are disposed in accordance with the distance from the neutron ray generation source 79 to the outer surface 70a of the casing 70. The first neutron ray scattering member 77a having a large thickness ta is disposed in the first direction (arrow Da) in which the distance from the neutron ray generation source 79 to the outer surface 70a of the casing 70 is a first distance, and is disposed at a position into which the neutron ray that is outgone in the first direction from the neutron ray generation source 79 can be incident. The second neutron ray scattering member 77b having a small thickness tb is disposed in the second direction (arrow Db) in which the distance from the neutron ray generation source 79 to the outer surface 70a of the casing 70 is a second distance which is longer than the first distance, and is disposed at a position into which the neutron ray that is outgone in the second direction from the neutron ray generation source 79 can be incident. On the other hand, the neutron ray scattering member is not disposed in the third direction (arrow Dc) in which the distance from the neutron ray generation source 79 to the outer surface 70a of the casing 70 is a third distance which is larger than the first distance and the second distance. The neutron ray scattering members 77a and 77b are disposed in this manner, so that the same effect of reducing the neutron dose rate as in the configuration of FIG. 1 can be expected.

In FIG. 3, since the neutron ray scattering members 77a and 77b are disposed closer to the neutron ray generation source 79, the amount of the neutron ray scattering members required is smaller than that of the neutron ray scattering members 76a and 76b in FIG. 1. Therefore, the disposition of the neutron ray scattering member in FIG. 3 may be more preferable than that in FIG. 1. However, various devices, cables, and the like are present around the device 78 configuring the beamline, and it is not always easy to dispose the neutron ray scattering member without a gap in the vicinity of the device 78. Therefore, in the present embodiment, while the neutron ray scattering members 76a and 76b mounted on the casing, as in FIG. 1, are used as a basis, the neutron ray scattering members 77a and 77b are also appropriately disposed in the vicinity of the device main body, as in FIG. 3. In this way, the neutron dose rate in the external space E of the casing is set to be equal to or lower than a reference value while reducing the total amount of the neutron ray scattering member in the entire device.

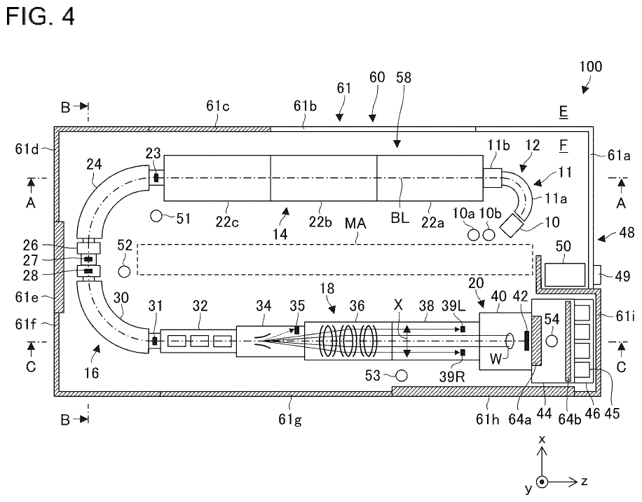

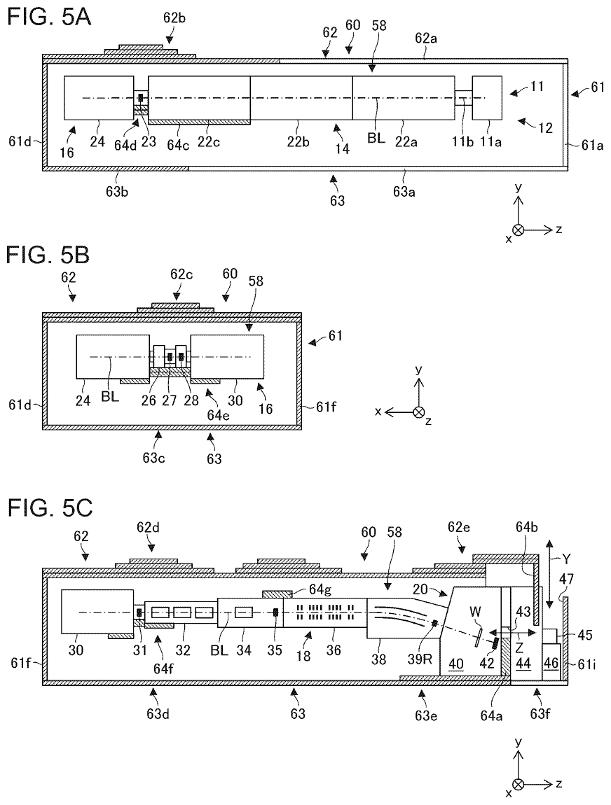

FIG. 4 is a top view schematically showing an ion implanter 100 according to the embodiment. FIGS. 5A to 5C are side views showing a schematic configuration of the ion implanter of FIG. 4. FIG. 5A corresponds to a cross section taken along line A-A of FIG. 4, FIG. 5B corresponds to a cross section taken along line B-B of FIG. 4, and FIG. 5C corresponds to a cross section taken along line C-C of FIG. 4.

The ion implanter 100 includes a device main body 58 and a casing 60. The device main body 58 includes a beam generation unit 12, a beam acceleration unit 14, a beam deflection unit 16, a beam transport unit 18, and a substrate transferring/processing unit 20. The casing 60 is disposed on the outer periphery of the device main body 58 and at least partially surrounds the device main body 58. Although details will be described later, the neutron ray scattering member is disposed at a location where hatching is applied in the drawing.

The beam generation unit 12 includes an ion source 10, a plurality of gas supply sources 10a and 10b, and a mass analyzer 11. The ion source 10 generates an ion beam by using a source gas that is supplied from each of the plurality of gas supply sources 10a and 10b. The first gas supply source 10a supplies a source gas of a first ion species, and the second gas supply source 10b supplies a source gas of a second ion species different from the first ion species. The ion source 10 generates an ion beam containing the first ion species or the second ion species by using the source gas that is supplied from the first gas supply source 10a or the second gas supply source 10b. The beam generation unit 12 may include three or more gas supply sources for supplying three or more types of source gases.

In the beam generation unit 12, an ion beam is extracted from the ion source 10, and the extracted ion beam is mass-analyzed by the mass analyzer 11. The mass analyzer 11 includes a mass analyzing magnet 11a and a mass analyzing slit 11b. The mass analyzing slit 11b is disposed on the downstream side of the mass analyzing magnet 11a. As a result of the mass analysis by the mass analyzer 11, an ion species necessary for the implantation is selected, and an ion beam of the selected ion species is led to the next beam acceleration unit 14.

The beam acceleration unit 14 includes a plurality of linear acceleration units 22a, 22b, and 22c that accelerate the ion beam, and a beam profile slit 23, and configures a portion of a beamline BL that extends linearly. Each of the plurality of linear acceleration units 22a to 22c includes one or more radio frequency resonators, and accelerates the ion beam by causing a radio frequency (RF) electric field to act on the ion beam. The beam profile slit 23 is provided in the most downstream of the beam acceleration unit 14, and is used to measure a beam profile of the high-energy ion beam accelerated by the plurality of linear acceleration units 22a to 22c.

In the present embodiment, three linear acceleration units 22a to 22c are provided. The first linear acceleration unit 22a is provided in an upper stage of the beam acceleration unit 14, and includes a plurality of stages (for example, stages in a range of 5 to 10 stages) of radio frequency resonators. The first linear acceleration unit 22a performs “bunching” for aligning the continuous beam (DC beam) output from the beam generation unit 12 with a specific acceleration phase, and accelerates the ion beam to, for example, energy of about 1 MeV. The second linear acceleration unit 22b is provided in a middle stage of the beam acceleration unit 14, and includes a plurality of stages (for example, stages in a range of 5 to 10 stages) of radio frequency resonators. The second linear acceleration unit 22b accelerates the ion beam output from the first linear acceleration unit 22a to energy in a range of about 2 to 3 MeV. The third linear acceleration unit 22c is provided in a lower stage of the beam acceleration unit 14 and includes a plurality of stages (for example, stages in a range of 5 to 10 stages) of radio frequency resonators. The third linear acceleration unit 22c accelerates the ion beam output from the second linear acceleration unit 22b to high energy of 4 MeV or higher.

In the present embodiment, the radio frequency resonators in a range of approximately 15 stages to 30 stages included in the beam acceleration unit 14 are divided and mounted on the three linear acceleration units 22a to 22c. However, the configuration of the beam acceleration unit 14 is not limited to that shown in the drawing. The beam acceleration unit 14 may be configured to be a single linear acceleration unit as a whole, or may be mounted to be divided into two linear acceleration units or four or more linear acceleration units. In addition, the beam acceleration unit 14 may be configured to include any other type of accelerator, and may include, for example, a tandem accelerator. The present embodiment is not limited to a specific ion acceleration method, and any beam accelerator can be adopted as long as the beam acceleration unit can generate an ultra-high energy ion beam of 4 MeV or higher. The high-energy ion beam that is output from the beam acceleration unit 14 has an energy distribution in a certain range. Therefore, in order to perform reciprocating scanning with and parallelization of the high-energy ion beam downstream of the beam acceleration unit 14 and irradiate the wafer with the ion beam, it is necessary to perform an energy analysis, a trajectory correction and adjustment of beam convergence and divergence with high accuracy in advance.

The beam deflection unit 16 performs the energy analysis, energy dispersion control, and trajectory correction of the high-energy ion beam output from the beam acceleration unit 14. The beam deflection unit 16 configures a portion of the beamline BL extending in an arc shape. The high-energy ion beam is turned in direction by the beam deflection unit 16 and is directed to the beam transport unit 18.

The beam deflection unit 16 includes an energy analyzing electromagnet 24, a laterally focusing quadrupole lens 26 that suppresses energy dispersion, an energy analyzing slit 27, a first Faraday cup 28, a bending electromagnet 30 that provides steering (trajectory correction), and a second Faraday cup 31. The energy analyzing electromagnet 24 is also referred to as an energy filter electromagnet (EFM). In addition, a device group including the energy analyzing electromagnet 24, the laterally focusing quadrupole lens 26, the energy analyzing slit 27, and the first Faraday cup 28 is also collectively referred to as an “energy analyzing device”.

The energy analyzing slit 27 is configured such that a slit width is variable to adjust the resolution of the energy analysis. For example, the energy analyzing slit 27 is configured to include two shielding members that are movable in the slit width direction, and is configured such that the slit width can be adjusted by changing the distance between the two shielding members. The energy analyzing slit 27 may be configured to have a variable slit width by selecting any one of a plurality of slits having different slit widths.

The first Faraday cup 28 is disposed immediately after the energy analyzing slit 27, and is used for measuring a beam current for energy analysis. The second Faraday cup 31 is disposed immediately after the bending electromagnet 30, and is provided for measuring the beam current of the ion beam that is trajectory-corrected and enters the beam transport unit 18. Each of the first Faraday cup 28 and the second Faraday cup 31 is configured to be able to be inserted into and removed from the beamline BL by the operation of a Faraday cup drive unit (not shown).

The beam transport unit 18 configures a portion of the beamline BL extending linearly, and is parallel to the beam acceleration unit 14 with a maintenance region MA of the device center interposed therebetween. The length of the beam transport unit 18 is designed to be approximately the same as the length of the beam acceleration unit 14. As a result, the beamline BL including the beam acceleration unit 14, the beam deflection unit 16, and the beam transport unit 18 has a U-shaped layout as a whole.

The beam transport unit 18 has a beam shaper 32, a beam scanner 34, a beam dump 35, a beam parallelizer 36, a final energy filter 38, and left and right Faraday cups 39L and 39R.

The beam shaper 32 includes a focusing/defocusing lens such as a quadrupole focusing/defocusing device (Q-lens), and is configured to shape the ion beam that has passed through the beam deflection unit 16 into a desired cross-sectional shape. The beam shaper 32 is configured to include, for example, an electric field type three-stage quadrupole lens (also referred to as a triplet Q-lens), and has three quadrupole lenses. The beam shaper 32 can independently adjust the convergence or divergence of the ion beam in each of the horizontal direction (x direction) and the vertical direction (y direction) by using the three lens devices. The beam shaper 32 may include a magnetic field type lens device, or may include a lens device that shapes a beam by using both an electric field and a magnetic field.

The beam scanner 34 is configured to provide reciprocating scanning with the beam and is a beam deflection device that performs scanning with the shaped ion beam in the x direction. The beam scanner 34 has a scanning electrode pair facing in a beam scanning direction (x direction). The scanning electrode pair is connected to a variable voltage power supply (not shown), and the voltage that is applied between the scanning electrode pair is periodically changed to change an electric field that is generated between the electrodes, thereby deflecting the ion beam at various angles. As a result, scanning with the ion beam is performed over a scanning range indicated by an arrow X. In FIG. 4, a plurality of trajectories of the ion beam in the scanning range are shown by a solid line.

The beam scanner 34 deflects the beam beyond the scanning range indicated by the arrow X to cause the ion beam to be incident into the beam dump 35 provided at a position away from the beamline BL. The beam scanner 34 blocks the ion beam such that the ion beam does not reach the substrate transferring/processing unit 20 on the downstream side by temporarily retreating the ion beam from the beamline BL toward the beam dump 35.

The beam parallelizer 36 is configured to cause a traveling direction of the scanning ion beam to be parallel to the trajectory of the designed beamline BL. The beam parallelizer 36 includes a plurality of parallelizing lens electrodes each having an arc shape with an ion beam passage slit provided in a central portion. The parallelizing lens electrode is connected to a high-voltage power supply (not shown), and causes an electric field generated by applying a voltage to act on the ion beam, thereby aligning the traveling direction of the ion beam in parallel. The beam parallelizer 36 may be replaced with another beam parallelizing device, and the beam parallelizing device may be configured as a magnetic device utilizing magnet field.

The final energy filter 38 is configured to analyze the energy of the ion beam and deflect the ion having the required energy downward (in a-y direction) to lead the ion to the substrate transferring/processing unit 20. The final energy filter 38 is sometimes referred to as an angular energy filter (AEF), and has an AEF electrode pair for electric field deflection. The AEF electrode pair is connected to a high-voltage power supply (not shown). In FIG. 5C, the ion beam is deflected downward by applying a positive voltage to the AEF electrode on the upper side and applying a negative voltage to the AEF electrode on the lower side. The final energy filter 38 may be configured to include a magnet device for magnetic field deflection or may be configured to include a combination of an AEF electrode pair for electric field deflection and a magnet device for a magnetic field deflection.

The left and right Faraday cups 39L and 39R are provided on the downstream side of the final energy filter 38, and are disposed at positions into which the beams at a left end and a right end of the scanning range indicated by the arrow X can be incident. The left and right Faraday cups 39L and 39R are provided at positions that do not block the beam toward the wafer W, and measure a beam current during the ion implantation into the wafer W.

The substrate transferring/processing unit 20 is provided on the downstream side of the beam transport unit 18, that is, the most downstream side of the beamline BL. The substrate transferring/processing unit 20 includes an implantation processing chamber 40, a beam monitor 42, a substrate transfer device 44, and a load port 46. The implantation processing chamber 40 is provided with a platen driving device (not shown) that holds the wafer W during the ion implantation and moves the wafer W in a direction (y direction) perpendicular to the beam scanning direction (X direction).

The beam monitor 42 is provided at the most downstream of the beamline BL inside the implantation processing chamber 40. The beam monitor 42 is provided at a position into which the ion beam can be incident in a case where the wafer W is not present on the beamline BL, and is configured to measure the beam current in advance of or between the ion implantation processes. The beam monitor 42 is located, for example, near a transfer port 43 that connects the implantation processing chamber 40 and the substrate transfer device 44 to each other, and is provided at a position vertically below the transport port 43.

The substrate transfer device 44 is configured to transfer the wafer W between the load port 46 on which a wafer container 45 is placed and the implantation processing chamber 40. The load port 46 is configured such that a plurality of wafer containers 45 can be loaded at the same time, and has, for example, four mounting tables arranged in the x direction. A wafer container transfer port 47 is provided vertically above the load port 46, and is configured such that the wafer container 45 can pass in the vertical direction as indicated by an arrow Y. For example, the wafer container 45 is automatically loaded into the load port 46 through the wafer container transfer port 47 by a transport robot installed on a ceiling or the like inside a semiconductor manufacturing factory where the ion implanter 100 is installed, and is automatically unloaded from the load port 46.

The ion implanter 100 further includes a central control device 50. The central control device 50 controls the entire operation of the ion implanter 100. The central control device 50 is realized by an element or a mechanical device including a CPU and a memory of a computer in terms of hardware, and is realized by a computer program in terms of software, and various functions that are provided by the central control device 50 can be realized by cooperation between hardware and software.

An operation panel 49 having a display device or an input device for setting an operation mode of the ion implanter 100 is provided in the vicinity of the central control device 50. Although the positions of the central control device 50 and the operation panel 49 are not particularly limited, for example, the central control device 50 and the operation panel 49 can be disposed adjacent to an entrance 48 of the maintenance region MA between the beam generation unit 12 and the substrate transferring/processing unit 20. The work efficiency can be improved by causing the locations of the ion source 10, the load port 46, the central control device 50, and the operation panel 49, which are frequently worked by a worker who manages the ion implanter 100, to be adjacent to each other.

The ion implanter 100 includes a neutron ray generation source capable of generating a neutron ray by collision of an ion beam having energy of 4 MeV or higher. The locations that can serve as neutron ray generation sources are members into which a high-energy ion beam can be continuously incident, and are a slit, a beam monitor, a beam dump, and the like. Specifically, as the slit that can serve as a neutron ray generation source, the beam profile slit 23, the energy analyzing slit 27, or the like can be given as an example. Further, as the beam monitor that can serve as a neutron ray generation source, the first Faraday cup 28, the second Faraday cup 31, the left and right Faraday cups 39L and 39R, the beam monitor 42, or the like can be given as an example. In addition, the beam dump 35 provided downstream of the beam scanner 34 can also serve as a neutron ray generation source. In FIGS. 4 and 5A to 5C, the components of the beamline that can serve as neutron ray generation sources are filled with black.

The ion implanter 100 includes a plurality of neutron ray measuring instruments 51, 52, 53, and 54 for measuring a neutron ray that can be generated inside the device. The dose rate of the neutron ray that can be generated in the ion implanter 100 is not so high and can be a value close to the detection limit of a general neutron ray measuring instrument. Therefore, the neutron ray measuring instrument is disposed in the vicinity of the neutron ray generation source in order to improve the measurement accuracy. The first neutron ray measuring instrument 51 is disposed in the vicinity of the beam profile slit 23, and the second neutron ray measuring instrument 52 is disposed in the vicinity of the energy analyzing slit 27 and the first Faraday cup 28. The third neutron ray measuring instrument 53 is disposed in the vicinity of the final energy filter 38 located between the beam dump 35 and the left and right Faraday cups 39L and 39R, and the fourth neutron ray measuring instrument 54 is disposed in the vicinity of the beam monitor 42.

In addition, the disposition of the neutron ray measuring instrument is merely an example, and the neutron ray measuring instruments may be disposed at locations less than or more than the shown locations. For example, a neutron ray measuring instrument that is added or replaced may be disposed in the vicinity of the second Faraday cup 31 or the beam dump 35. In addition, a plurality of neutron ray measuring instruments may be provided at the same location, and for example, each of the neutron ray measuring instruments 51 to 54 disposed at four locations in FIG. 4 may have a plurality of (for example, two or three) neutron ray measuring instruments.

The casing 60 scatters the neutron ray generated in the device main body 58, and causes the neutron dose rate in the external space E outside the casing 60 to be equal to or less than a predetermined reference value. As shown in FIGS. 5A to 5C, the casing 60 includes a side wall portion 61 provided on the side of the device main body 58, a ceiling portion 62 provided vertically above the device main body 58, and a floor portion 63 provided vertically below the device main body. The casing 60 surrounds the internal space F having a substantially rectangular parallelepiped shape occupied by the device main body 58.

The side wall portion 61, the ceiling portion 62, or the floor portion 63 is at least partially mounted with a neutron ray scattering member. On the other hand, a neutron ray scattering member is not mounted on a part of the casing 60 which is disposed along a partial section of the beamline, that is, a part of each of the side wall portion 61, the ceiling portion 62, and the floor portion 63. In the drawings, the neutron ray scattering member is provided at a location with hatching, and the neutron ray scattering member is not provided at a location without hatching.

At least a part of the side wall portion 61, the ceiling portion 62, or the floor portion 63 can be configured, for example, in the same manner as the accommodation portion 71 or the non-accommodation portion 72 described above. A slide door or a hinged door may be provided at any position of the casing 60, and a neutron ray scattering member may be mounted on the door structure.

The side wall portion 61 includes a first side wall portion 61a disposed in the vicinity or around the beam generation unit 12. The beam generation unit 12 is a location through which an ion beam with low energy before being accelerated to high energy passes, and does not serve as a neutron ray generation source. In addition, the first side wall portion 61a is provided at a position separated by a distance in a range of 5 m to 10 m or more from the neutron ray generation source, and is not provided with a neutron ray scattering member. For example, the first side wall portion 61a is configured in the same manner as the non-accommodation portion 72 described above.

The side wall portion 61 includes a second side wall portion 61b and a third side wall portion 61c that are disposed along the beam acceleration unit 14. The second side wall portion 61b is not provided with a neutron ray scattering member because the second side wall portion 61b is disposed along the first linear acceleration unit 22a and the second linear acceleration unit 22b through which the ion beam before being accelerated to high energy passes. On the other hand, the third side wall portion 61c is a portion disposed along the third linear acceleration unit 22c through which the high-energy ion beam passes, and is disposed in the vicinity of the beam profile slit 23 that can serve as a neutron ray generation source, so that a neutron ray scattering member is provided. For example, the second side wall portion 61b is configured in the same manner as the non-accommodation portion 72 described above. For example, the third side wall portion 61c is configured in the same manner as the accommodation portion 71 described above. The third side wall portion 61c is configured in the same manner as the second accommodation portion 71b, and a second neutron ray scattering member 76b having a small thickness may be provided.

The side wall portion 61 includes a fourth side wall portion 61d, a fifth side wall portion 61e, and a sixth side wall portion 61f that are disposed along the beam deflection unit 16. The beam deflection unit 16 includes the energy analyzing slit 27, the first Faraday cup 28, and the second Faraday cup 31 that can serve as neutron ray generation sources. Therefore, neutron ray scattering members are provided in the side wall portions 61d to 61f in the vicinity of the beam deflection unit 16.

The fourth side wall portion 61d is disposed in the vicinity of the energy analyzing electromagnet 24 in which the beamline BL is arc-shaped. Therefore, the distance from the beamline BL to the fourth side wall portion 61d is relatively large. Therefore, a neutron ray scattering member having a small thickness is provided in the fourth side wall portion 61d. Similarly, the sixth side wall portion 61f is disposed in the vicinity of the bending electromagnet 30 in which the beamline BL is arc-shaped, and the distance from the beamline BL to the sixth side wall portion 61f is relatively large. Therefore, a neutron ray scattering member having a small thickness is provided. The fourth side wall portion 61d and the sixth side wall portion 61f may be configured in the same manner as the second accommodation portion 71b described above, and the second neutron ray scattering member 76b having a small thickness may be provided.

The fifth side wall portion 61e is disposed in the vicinity of the laterally focusing quadrupole lens 26, the energy analyzing slit 27, and the first Faraday cup 28, in which the beamline BL is linear, and is parallel to the beamline BL. The fifth side wall portion 61e is disposed close to the beamline BL from the viewpoint of reducing the occupied area of the casing 60. The distance from the energy analyzing slit 27 or the first Faraday cup 28, which serves as a neutron ray generation source, to the fifth side wall portion 61e is small and is, for example, 2 m or less, 1.5 m or less, or 1 m or less. Further, the neutron ray from the energy analyzing slit 27 or the first Faraday cup 28 toward the fifth side wall portion 61e progresses in the thickness direction of the fifth side wall portion 61e. Therefore, it is also difficult to secure an effective thickness through which the neutron ray passes. Therefore, a neutron ray scattering member having a large thickness is provided in the fifth side wall portion 61e, and the thickness thereof is, for example, 150 mm or more, 200 mm or more, or 300 mm or more. The fifth side wall portion 61e may be configured in the same manner as the first accommodation portion 71a described above, and a first neutron ray scattering member 76a having a large thickness may be provided.

The side wall portion 61 includes a seventh side wall portion 61g disposed along the beam transport unit 18. The seventh side wall portion 61g is disposed in the vicinity of the beam shaper 32, the beam scanner 34, and the beam parallelizer 36 which are located on the upstream side of the beam transport unit 18. Although the second Faraday cup 31 or the beam dump 35, which can serve as a neutron ray generation source, is present in the vicinity of the seventh side wall portion 61g, the distance from the neutron ray generation source to the seventh side wall portion 61g is relatively large. Therefore, a neutron ray scattering member having a small thickness is provided in the seventh side wall portion 61g. The seventh side wall portion 61g may be configured in the same manner as the second accommodation portion 71b described above, and the second neutron ray scattering member 76b having a small thickness may be provided.

The side wall portion 61 includes an eighth side wall portion 61h disposed along the final energy filter 38, the implantation processing chamber 40, and the substrate transfer device 44. The eighth side wall portion 61h is disposed in the vicinity of the beam monitor 42 into which the high-energy ion beam can be frequently incident, and a neutron dose rate in the beam monitor 42 is relatively high. Therefore, a neutron ray scattering member having a large thickness is provided. The eighth side wall portion 61h may be configured in the same manner as the first accommodation portion 71a described above, and the first neutron ray scattering member 76a having a large thickness may be provided.

The side wall portion 61 includes a ninth side wall portion 61i disposed to surround the load port 46. The ninth side wall portion 61i has a portion that is disposed on the front side of the load port 46 and a portion that is disposed on the side of the load port 46. The ninth side wall portion 61i is provided with an entrance to the load port 46 and a front door. Since the ninth side wall portion 61i is disposed in the vicinity of the beam monitor 42, a neutron ray scattering member is provided. Since the ninth side wall portion 61i is close to the beam monitor 42, it is preferable to provide a neutron ray scattering member having a large thickness. However, when the thickness of the front door is too large, it is laborious to open and close the front door, which leads to a decrease in convenience. Therefore, additional neutron ray scattering members 64a and 64b are disposed between the beam monitor 42 and the load port 46, so that the thickness of the neutron ray scattering member required for the ninth side wall portion 61i is reduced. The ninth side wall portion 61i may be configured in the same manner as the second accommodation portion 71b described above, and the second neutron ray scattering member 76b having a small thickness may be provided.

It should be noted that neutron ray scattering members are also provided on the ceiling portion 62 and the floor portion 63 in the same manner as that in the side wall portion 61. That is, a neutron ray scattering member is intensively disposed in the vicinity of the neutron ray generation source or at a location where the distance from the neutron ray generation source to the ceiling portion 62 or the floor portion 63 is short, and at other locations, the neutron ray scattering member is made thin or the neutron ray scattering member is not provided.

In FIG. 5A, the ceiling portion 62 includes a first ceiling portion 62a where a neutron ray scattering member is not provided and a second ceiling portion 62b where a neutron ray scattering member is provided. The first ceiling portion 62a is disposed along the beam generation unit 12 and the upstream side (the first linear acceleration unit 22a and the second linear acceleration unit 22b) of the beam acceleration unit 14. The second ceiling portion 62b is disposed along the downstream side (the third linear acceleration unit 22c and the beam profile slit 23) of the beam acceleration unit 14. Since the second ceiling portion 62b is close to the beam profile slit 23 that can serve as a neutron ray generation source (for example, within 1 m), the thickness of the neutron ray scattering member is stepwise changed in accordance with the distance from the beam profile slit 23. For example, in the second ceiling portion 62b, the number of overlapping the plate-like neutron ray scattering members increases as the distance from the beam profile slit 23 decreases.

In FIG. 5A, the floor portion 63 includes a first floor portion 63a where a neutron ray scattering member is not provided and a second floor portion 63b where a neutron ray scattering member is provided. The first floor portion 63a is disposed along the beam generation unit 12 and the upstream side of the beam acceleration unit 14. The second floor portion 63b is disposed in the vicinity of the beam profile slit 23. It is preferable that the floor portion 63 is configured to be as flat as possible from the viewpoint of securing a scaffold at the time of mounting of the device main body 58 or working. In other words, it is not preferable that the upper surface of the floor portion 63 is configured to have a stair shape by partially disposing a neutron ray scattering member having a large thickness on the floor portion 63. Therefore, additional neutron ray scattering members 64c and 64d are disposed on the lower surface of the device that accommodates the third linear acceleration unit 22c and the beam profile slit 23, so that the thickness of the neutron ray scattering member required for the second floor portion 63b is reduced.

In FIG. 5B, the ceiling portion 62 includes a third ceiling portion 62c where a neutron ray scattering member is provided. The third ceiling portion 62c is disposed along the beam deflection unit 16. The third ceiling portion 62c is configured such that the thickness of the neutron ray scattering member increases as the distance from the neutron ray generation source becomes shorter in the vicinity of the energy analyzing slit 27 or the first Faraday cup 28 which can serve as a neutron ray generation source, as with the second ceiling portion 62b.

In FIG. 5B, the floor portion 63 includes a third floor portion 63c where a neutron ray scattering member is provided. The third floor portion 63c is disposed along the beam deflection unit 16. In addition, an additional neutron ray scattering member 64e is disposed on the lower surface of the device configuring the beam deflection unit 16. The additional neutron ray scattering member 64e is disposed in the vicinity of the energy analyzing slit 27 or the first Faraday cup 28 that can serve as a neutron ray generation source, and is configured such that the thickness of the neutron ray scattering member increases as the distance from the neutron ray generation source becomes shorter. The additional neutron ray scattering member 64e is disposed, so that the thickness of the neutron ray scattering member required for the third floor portion 63c is reduced.

In FIG. 5C, the ceiling portion 62 includes a fourth ceiling portion 62d and a fifth ceiling portion 62e where neutron ray scattering members are provided. The fourth ceiling portion 62d is disposed along the beam transport unit 18, and the fifth ceiling portion 62e is disposed along the substrate transferring/processing unit 20. The fourth ceiling portion 62d is configured such that the thickness of the neutron ray scattering member increases in the vicinity of each of the second Faraday cup 31 and the beam dump 35 which can serve as neutron ray generation sources. In addition, an additional neutron ray scattering member 64g is provided at a position near the beam dump 35 on the upper surface of the beam scanner 34. The fifth ceiling portion 62e is configured such that the thickness of the neutron ray scattering member increases as the distance from the beam monitor 42 that can serve as a neutron ray generation source becomes shorter.

In FIG. 5C, the floor portion 63 includes a fourth floor portion 63d and a fifth floor portion 63e where neutron ray scattering members are provided. The fourth floor portion 63d is disposed along the beam transport unit 18, and the fifth floor portion 63e is disposed along the substrate transferring/processing unit 20. The fourth floor portion 63d is configured such that the thickness of the neutron ray scattering member becomes uniform. An additional neutron ray scattering member 64f is disposed on the lower surface of the device main body 58 in the vicinity of the second Faraday cup 31. The additional neutron ray scattering member 64f is disposed, so that the thickness of the neutron ray scattering member required for the fourth floor portion 63d is reduced. The fifth floor portion 63e is configured such that the thickness of the neutron ray scattering member increases in the vicinity of the implantation processing chamber 40 in which the beam monitor 42 is provided. A neutron ray scattering member is not provided in the floor portion (sixth floor portion) 63f of the substrate transfer device 44 and the load port 46. This is because the additional neutron ray scattering member 64a disposed between the implantation processing chamber 40 and the substrate transfer device 44 can sufficiently reduce the neutron dose rate from the beam monitor 42 toward the sixth floor portion 63f.

In FIG. 5C, the additional neutron ray scattering members 64a and 64b provided in the substrate transferring/processing unit 20 are disposed so as not to hinder the transfer of the wafer W between the implantation processing chamber 40 and the load port 46. Specifically, a configuration is made such that a neutron ray scattering member is not disposed on the wafer transfer path in the horizontal direction indicated by an arrow Z at a height position where the transfer port 43 is provided. That is, the additional neutron ray scattering members 64a and 64b are disposed so as not to overlap each other in the horizontal direction. On the other hand, in order to prevent the neutron ray from leaking to the outside through the wafer transfer path in the horizontal direction indicated by the arrow Z, the ninth side wall portion 61i including a neutron ray scattering member is provided on the front side of the load port 46. The ninth side wall portion 61i is disposed to partially overlap with each of the additional neutron ray scattering members 64a and 64b in the horizontal direction.

In FIG. 5C, the additional neutron ray scattering member 64b provided in the substrate transferring/processing unit 20 is disposed so as not to hinder the transport of the wafer container in the vertical direction indicated by the arrow Y through the wafer container transfer port 47. That is, the additional neutron ray scattering member 64b is disposed away from the ninth side wall portion 61i in the horizontal direction with the wafer container transfer port 47 interposed therebetween. On the other hand, in order to prevent the neutron ray from leaking to the outside through the wafer container transfer port 47, the additional neutron ray scattering member 64b and the ninth side wall portion 61i are disposed to partially overlap each other in the horizontal direction.

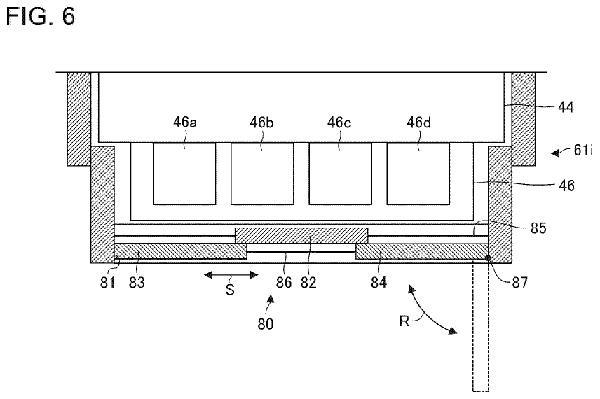

FIG. 6 is a top view schematically showing the structure of a front door 80 of the load port 46. The load port 46 includes four mounting tables 46a to 46d arranged in one row in a left-right direction (the direction of an arrow S). An entrance 81 surrounded by a part of the ninth side wall portion 61i in FIG. 4 is provided on the front side of the load port 46, and two slide doors 82 and 83 and one hinged door 84 are provided such that the entrance 81 can be closed. A neutron ray scattering member is mounted on each of the doors 82 to 84 configuring the front door 80.

The first slide door 82 is configured to be slidable in the left-right direction along a first rail 85 extending in the left-right direction, and the second slide door 83 is configured to be slidable in the left-right direction along a second rail 86 extending in the left-right direction. The first slide door 82 and the second slide door 83 are disposed at positions different from each other in a depth direction, and the first slide door 82 is disposed on the rear side and the second slide door 83 is disposed on the front side when viewed from the front side of the load port 46. The hinged door 84 is configured to be pivotable with a hinge 87 provided at the right end of the entrance 81 as a rotation axis, as indicated by an arrow R.

In the closed state of the front door 80 shown in FIG. 6, the first slide door 82 is disposed at the center of the entrance 81, the second slide door 83 is disposed on the left side of the entrance 81, and the hinged door 84 is disposed on the right side of the entrance 81. In other words, the hinged door 84 closes the right end of the entrance 81, and the two slide doors 82 and 83 close the remaining portion of the entrance 81 that is not closed by the hinged door 84. In the closed state, the first slide door 82 and the second slide door 83 are configured to partially overlap each other in the depth direction, and the first slide door 82 and the hinged door 84 are also configured to partially overlap each other in the depth direction. The hinged door 84 is configured such that the position of the hinged door 84 in the depth direction coincides with the position of the second slide door 83 in the depth direction in the closed state.

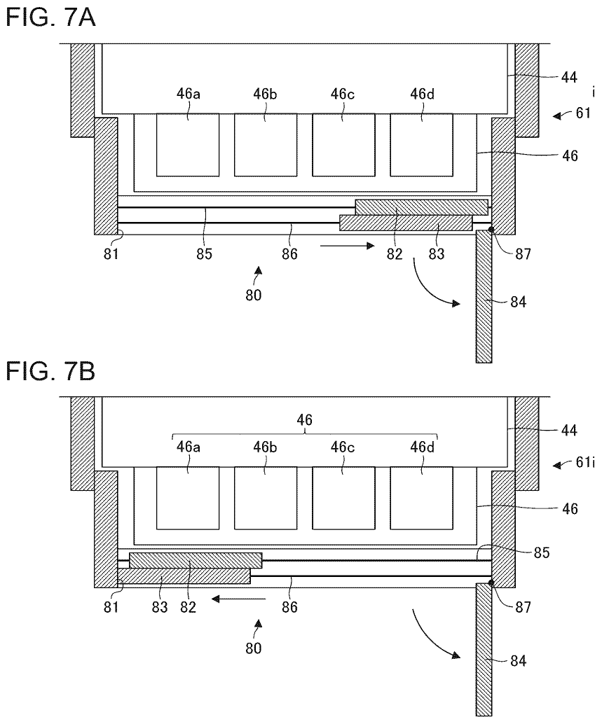

FIGS. 7A and 7B are top views schematically showing the front door 80 in the open state. FIG. 7A shows a state where the left side of the entrance 81 is open. The hinged door 84 is opened toward the front, and the first slide door 82 and the second slide door 83 are slid to the right side of the entrance 81. As a result, the front sides of both the first mounting table 46a and the second mounting table 46b disposed on the left side are opened. FIG. 7B shows a state in which the right side of the entrance 81 is open. The hinged door 84 is opened toward the front, and the first slide door 82 and the second slide door 83 are slid to the left side of the entrance 81. As a result, the front sides of both the third mounting table 46c and the fourth mounting table 46d disposed on the right side are opened.

According to the present embodiment, in the load port 46 provided with the four mounting tables 46a to 46d, the three doors 82 to 84 are combined with each other, so that in the open state, the entire front side of two mounting tables on either the left side or the right side can be opened, and a work space having a margin in the left-right direction can be provided. In a case where the front door 80 is configured to include only two slide doors, since the two slide doors are disposed to overlap each other in the vicinity of the center of the entrance 81, the front of the two center mounting tables 46b and 46c cannot be widely opened. In addition, in a case where the front door 80 is configured to include three slide doors, the three slide doors need to be disposed to be shifted in the depth direction, and the thickness of the entire front door 80 in the depth direction increases. In the present embodiment, since a neutron ray scattering member having a large thickness (for example, about 200 mm) is mounted on each of the doors 82 to 84 configuring the front door 80, the depth of the front door 80 becomes large in a case where the three slide doors are adopted. On the other hand, according to the present embodiment, the two slide doors and the one hinged door are combined with each other, so that the entrance 81 can be widely opened while reducing the depth of the front door 80.

In the front door 80 shown in FIGS. 6, 7A, and 7B, the hinged door 84 is provided on the right side of the entrance 81. However, the hinged door 84 may be provided on the left side of the entrance 81. That is, the front door 80 may be configured to be left-right symmetrical with the shown structure. Alternatively, a configuration may be made such that a first hinged door is disposed on the left side of the entrance 81, a second hinged door is disposed on the right side of the entrance 81, and a single slide door is disposed in the center of the entrance 81.

Subsequently, the measurement of the neutron ray will be described. The central control device 50 acquires the measured value of each of the plurality of neutron ray measuring instruments 51 to 54 shown in FIG. 4, and monitors the generation status of the neutron ray. The central control device 50 estimates the position of at least one neutron ray generation source, based on the measured values of the plurality of neutron ray measuring instruments 51 to 54, and estimates the neutron ray intensity emitted from the at least one neutron ray generation source whose position is estimated.

For example, in a case where the neutron ray is detected by the first neutron ray measuring instrument 51 or the second neutron ray measuring instrument 52 while the neutron ray is not detected by the third neutron ray measuring instrument 53 or the fourth neutron ray measuring instrument 54, it is estimated that the neutron ray generation source is located on the upstream side of the beamline BL. In this case, the magnitude of the measured value of each of the first neutron ray measuring instrument 51 and the second neutron ray measuring instrument 52 is analyzed, so that it is possible to estimate which neutron ray generation source is generating the neutron ray. For example, in a case where the measured value of the first neutron ray measuring instrument 51 is large and the measured value of the second neutron ray measuring instrument 52 is small, it is estimated that the beam profile slit 23 is a neutron ray generation source. In addition, in a case where the measured value of the first neutron ray measuring instrument 51 is small and the measured value of the second neutron ray measuring instrument 52 is large, it is estimated that at least one of the energy analyzing slit 27, the first Faraday cup 28, and the second Faraday cup 31 is a neutron ray generation source. In addition, in a case where both the measured value of the first neutron ray measuring instrument 51 and the measured value of the second neutron ray measuring instrument 52 are large, it is estimated that all of the beam profile slit 23, the energy analyzing slit 27, the first Faraday cup 28, and the second Faraday cup 31 are neutron ray generation sources. Conversely, in a case where the neutron ray is not detected by the first neutron ray measuring instrument 51 and the second neutron ray measuring instrument 52 and the neutron ray is detected by the third neutron ray measuring instrument 53 or the fourth neutron ray measuring instrument 54, it is estimated that a neutron ray generation source is located on the downstream side of the beamline BL. By estimating the position of the neutron ray generation source, it is also possible to estimate the intensity of the neutron ray emitted from the neutron ray generation source whose position is estimated, based on the disposition or the distances of the plurality of neutron ray measuring instruments 51 to 54 with respect to the neutron ray generation source whose position is estimated.

The central control device 50 may estimate the dose rate distribution of the neutron ray in the internal space F inside the casing 60, based on the measured values of the plurality of neutron ray measuring instruments 51 to 54. The central control device 50 may estimate the neutron dose rate outside the casing 60, based on the measured values of the plurality of neutron ray measuring instruments 51 to 54. For example, the central control device 50 may estimate the position of the neutron ray generation source and the neutron dose rate, and calculate the neutron dose rate at any position in the internal space For the external space E of the casing 60 by simulation or the like, based on the estimated position of the neutron ray generation source and the estimated neutron dose rate. The neutron dose rate inside or outside the casing 60 may be calculated in consideration of the disposition of the device main body 58, the disposition of the casing 60, the disposition of the neutron ray scattering member provided in the casing 60, and the disposition of the neutron ray scattering member provided separately from the casing 60. In a case where the calculated neutron dose rate inside or outside the casing 60 exceeds a predetermined upper limit value, the central control device 50 may output an alert, temporarily stop the output of the ion beam, or change at least one operation condition of a plurality of devices configuring the device main body 58 such that the neutron dose rate becomes smaller than the upper limit value.

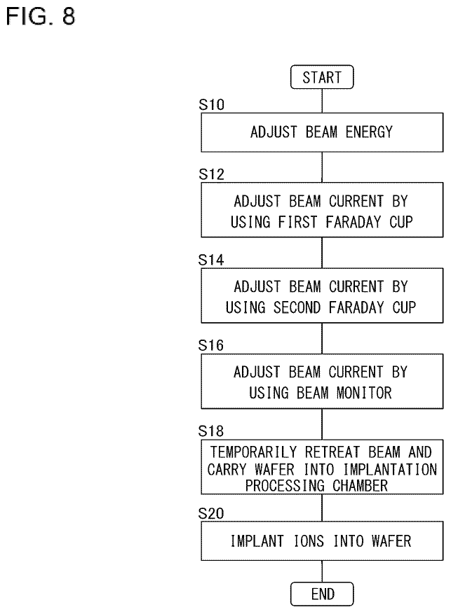

The central control device 50 may monitor at least one of the plurality of devices disposed along the beamline BL, based on the measured values of the plurality of neutron ray measuring instruments 51 to 54. Specifically, abnormality of at least one of the plurality of devices configuring the device main body 58 may be detected, or a device requiring maintenance among the plurality of devices may be estimated. The central control device 50 may determine whether at least one device to be monitored is normal or abnormal by using information about the operation mode of the device main body 58. This is because the place serving as a neutron ray generation source or the neutron dose rate generated in the neutron ray generation source may be different depending on the operation mode of the device main body 58. Hereinafter, some operation modes in each of which a neutron ray can be generated will be described with reference to FIGS. 8 to 14.

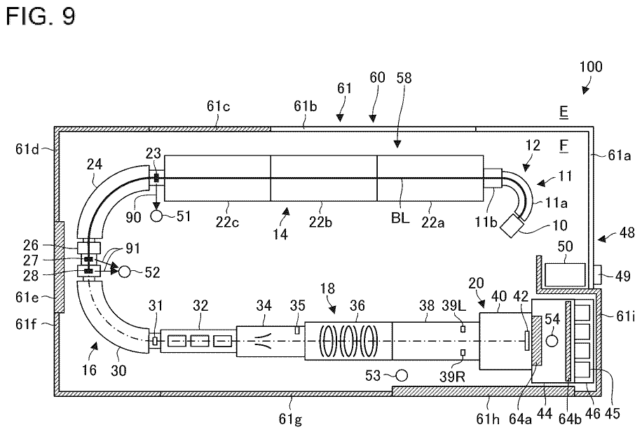

FIG. 8 is a flowchart showing a flow of the ion implantation process according to the embodiment, and shows a flow of implanting ions into the wafer W after adjusting the ion beam. FIGS. 9 to 14 schematically show the operation mode of the device main body 58 in each process, the position of the neutron ray generation source, and neutron rays 90 to 97 that are detected by the plurality of neutron ray measuring instruments 51 to 54. In each of FIGS. 9 to 14, the range of the ion beam passing through the beamline BL is indicated by a thick line, and the main neutron ray generation source is filled with black.

First, in a first process (S10) of FIG. 8, the beam energy is adjusted. FIG. 9 schematically shows the ion implanter 100 in the first process. The first process is performed in a state where the beam profile slit 23 is inserted into the beamline BL, the slit width of the energy analyzing slit 27 is narrowed, and the first Faraday cup 28 is inserted into the beamline BL (also referred to as a first operation mode). In the first process, there is a possibility that the high-energy ion beam collides with the beam profile slit 23, the energy analyzing slit 27, and the first Faraday cup 28 and a neutron ray is generated. Therefore, in the first process, the beam profile slit 23, the energy analyzing slit 27, and the first Faraday cup 28 can serve as neutron ray generation sources. At this time, the neutron ray 90 generated in the beam profile slit 23 is mainly detected by the first neutron ray measuring instrument 51. In addition, the neutron ray 91 generated in the energy analyzing slit 27 or the first Faraday cup 28 is mainly detected by the second neutron ray measuring instrument 52. The neutron ray 90 generated in the beam profile slit 23 can also be detected by the second neutron ray measuring instrument 52. Similarly, the neutron ray 91 generated in the energy analyzing slit 27 or the first Faraday cup 28 can also be detected by the first neutron ray measuring instrument 51.

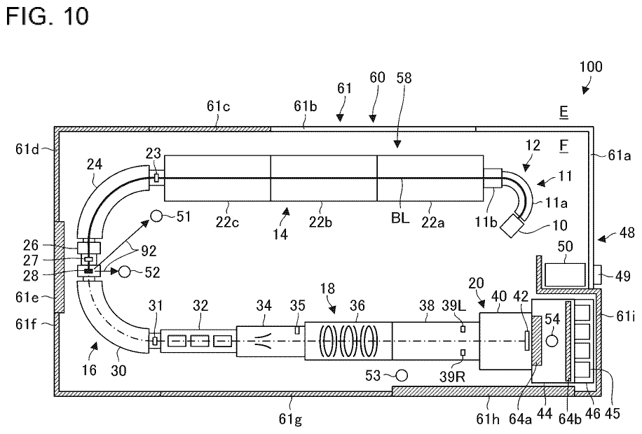

Subsequently, in a second process (S12) of FIG. 8, the beam current is adjusted by using the first Faraday cup 28. FIG. 10 schematically shows the ion implanter 100 in the second process. The second process is performed in a state where the beam profile slit 23 is retreated from the beamline BL, the slit width of the energy analyzing slit 27 is widened to a normal width, and the first Faraday cup 28 is inserted into the beamline BL (also referred to as a second operation mode). The second process is an operation mode similar to the first process in FIG. 9. However, the high-energy ion beam does not collide with the beam profile slit 23, and the high-energy ion beam is less likely to collide with the energy analyzing slit 27. As a result, in the second process, the high-energy ion beam substantially collides with only the first Faraday cup 28, and the first Faraday cup 28 can serve as a neutron ray generation source. The neutron ray 92 generated in the first Faraday cup 28 can be detected by the first neutron ray measuring instrument 51 or the second neutron ray measuring instrument 52. In the second process, since more high-energy ion beams are incident into the first Faraday cup 28, the dose rate of the neutron ray 92 that can be generated in the first Faraday cup 28 becomes higher than that in the first process.

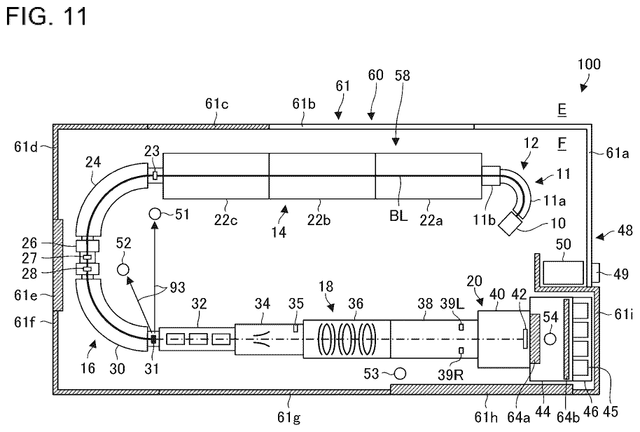

Next, in a third process (S14) of FIG. 8, the beam current is adjusted by using the second Faraday cup 31. FIG. 11 schematically shows the ion implanter 100 in the third process. The third process is performed in a state where the first Faraday cup 28 is retreated from the beamline BL and the second Faraday cup 31 is inserted into the beamline BL (also referred to as a third operation mode). In the third process, since the ion beam collides with the second Faraday cup 31, the second Faraday cup 31 can serve as a main neutron ray generation source. The neutron ray 93 generated in the second Faraday cup 31 is mainly detected by the first neutron ray measuring instrument 51 and the second neutron ray measuring instrument 52. At this time, the dose rate of the neutron ray 93 that is detected by the second neutron ray measuring instrument 52 disposed in the vicinity of the second Faraday cup 31 is relatively large, and the dose rate of the neutron ray 93 that is detected by the first neutron ray measuring instrument 51 disposed away from the second Faraday cup 31 is relatively small.

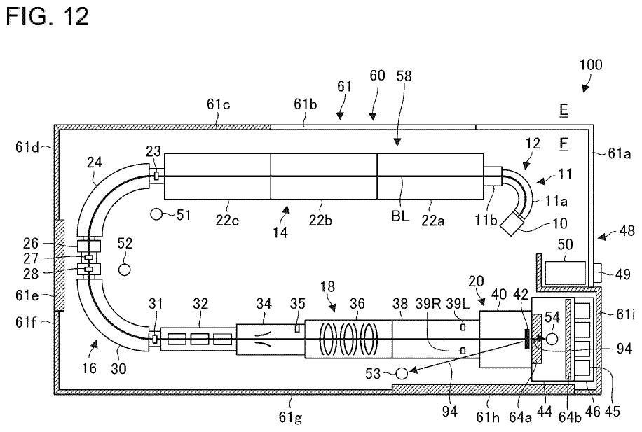

Next, in a fourth process (S16) of FIG. 8, the beam current is adjusted by using the beam monitor 42. FIG. 12 schematically shows the ion implanter 100 in the fourth process. The fourth process is performed in an unscanning state where the second Faraday cup 31 is retreated from the beamline BL and reciprocating scanning with the ion beam is not performed by the beam scanner 34 (also referred to as a fourth operation mode). In the fourth process, since the ion beam collides with the beam monitor 42, the beam monitor 42 can serve as a main neutron ray generation source. The neutron ray 94 generated in the beam monitor 42 is mainly detected by the third neutron ray measuring instrument 53 and the fourth neutron ray measuring instrument 54. At this time, the dose rate of the neutron ray 94 that is detected by the fourth neutron ray measuring instrument 54 disposed in the vicinity of the beam monitor 42 is relatively large, and the dose rate of the neutron ray 94 that is detected by the third neutron ray measuring instrument 53 disposed away from the beam monitor 42 is relatively small.

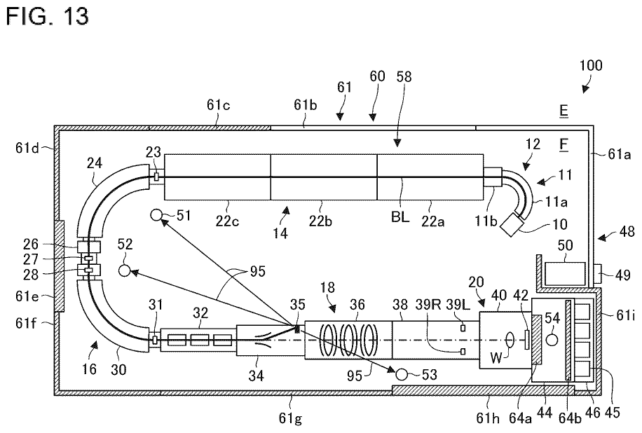

Next, in a fifth process (S18) of FIG. 8, the ion beam is temporarily retreated from the beamline BL, and the wafer W to be ion-implanted is carried into the implantation processing chamber 40. FIG. 13 schematically shows the ion implanter 100 in the fifth process. In the fifth process, a state where the ion beam is deflected by using the beam scanner 34 and the ion beam is incident into the beam dump 35 (also referred to as a fifth operation mode) is set. Therefore, in the fifth process, the beam dump 35 can serve as a main neutron ray generation source. The neutron ray 95 generated in the beam dump 35 is mainly detected by the first neutron ray measuring instrument 51, the second neutron ray measuring instrument 52, and the third neutron ray measuring instrument 53. At this time, the dose rate of the neutron ray 95 that is detected by the third neutron ray measuring instrument 53 disposed in the vicinity of the beam dump 35 is relatively large, and the dose rate of the neutron ray 95 that is detected by the first neutron ray measuring instrument 51 or the second neutron ray measuring instrument 52 disposed away from the beam dump 35 is relatively small.

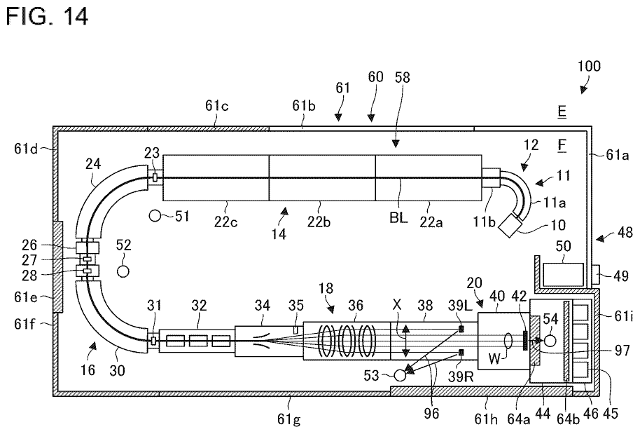

Next, in a sixth process (S20) of FIG. 8, the ion implantation processing is performed by irradiating the wafer W with the ion beam performing the reciprocating scanning by using the beam scanner 34. FIG. 14 schematically shows the ion implanter 100 in the sixth process. In the sixth process, the reciprocating scanning with the ion beam is performed by using the beam scanner 34 and the ion beam is incident into the left and right Faraday cups 39L and 39R. In addition, in the sixth process, a state where the wafer W reciprocates in the vertical direction and at least a portion of the ion beam that is not incident the wafer W is incident into the beam monitor 42 (also referred to as a sixth operation mode) is set. Therefore, in the sixth process, the left and right Faraday cups 39L and 39R and the beam monitor 42 can serve as main neutron ray generation sources. The neutron rays 96 generated in the left and right Faraday cups 39L and 39R are mainly detected by the third neutron ray measuring instrument 53, and the neutron ray 97 generated in the beam monitor 42 is mainly detected by the fourth neutron ray measuring instrument 54. In the sixth process, since a part of the ion beam reaching the implantation processing chamber 40 is incident into the beam monitor 42, the neutron dose rate that can be generated in the beam monitor 42 becomes lower than that in the fourth process, and the dose rate of the neutron ray 97 that is detected by the fourth neutron ray measuring instrument 54 also becomes lower.

In addition, the device main body 58 can take various operation modes depending on the state of the device main body 58 in addition to the operation mode corresponding to each of the first process to the sixth process.

In this manner, when the operation mode of the device main body 58 is changed, the location that can serve as a neutron ray generation source is changed, and the neutron dose rate generated in the neutron ray generation source can also be changed. Therefore, the central control device 50 performs abnormality detection according to the operation mode of the device main body 58. The central control device 50 monitors the device, based on information about the operation mode of the device main body 58 and the measured value of at least one of the neutron ray measuring instruments in a specific operation mode. For example, the reference for the abnormality detection may be changed according to the operation mode, and at least one of the plurality of devices may be monitored by using the reference according to the operation mode. In addition, in a case where the measured value of at least one of the neutron ray measuring instruments exceeds a reference value determined to correspond to a specific operation mode, the operation condition of at least one of the plurality of devices may be changed such that the measured value becomes equal to or smaller than the reference value. For example, the operation condition may be changed such that the neutron dose rate decreases, or the beam output may be temporarily stopped such that the neutron ray is not generated.

In the case of the first operation mode of FIG. 9 or the second operation mode of FIG. 10, it can be said that a state is normal where there is a possibility that the neutron rays 90, 91, and 92 are detected by the first neutron ray measuring instrument 51 or the second neutron ray measuring instrument 52, while the neutron ray is not detected by the third neutron ray measuring instrument 53 or the fourth neutron ray measuring instrument 54. Therefore, in the first operation mode or the second operation mode, the upper limit values of the first neutron ray measuring instrument 51 and the second neutron ray measuring instrument 52 are set to be high, and the upper limit values of the third neutron ray measuring instrument 53 and the fourth neutron ray measuring instrument 54 are set to be low (for example, near a background noise level). In this way, in a case where the neutron ray is detected by the third neutron ray measuring instrument 53 or the fourth neutron ray measuring instrument 54, it is possible to detect that some abnormality has occurred in the ion implanter 100. The beam energy or the beam current may be adjusted while monitoring the neutron ray generated by at least one of the beam acceleration unit 14 and the beam deflection unit 16 by using the first neutron ray measuring instrument 51 and the second neutron ray measuring instrument 52. In this way, in a case where the measured value of the first neutron ray measuring instrument 51 or the second neutron ray measuring instrument 52 exceeds the upper limit value, it is possible to detect that some abnormality has occurred in the adjustment process of the first operation mode or the second operation mode.

In the case of the third operation mode of FIG. 11, since the second Faraday cup 31 can serve as a main neutron ray generation source, it can be said that a state is normal where the neutron ray is not detected by the first neutron ray measuring instrument 51 or the second neutron ray measuring instrument 52 or a trace amount of neutron ray can be detected. For example, it can be said that a state is normal where the neutron dose rate that is detected by the first neutron ray measuring instrument 51 disposed away from the second Faraday cup 31 is smaller than the neutron dose rate that is detected by the second neutron ray measuring instrument 52 disposed in the vicinity of the second Faraday cup 31. Therefore, in the third operation mode, the beam current may be adjusted while monitoring the neutron ray generated in the second Faraday cup 31 downstream of the energy analyzing device by using the first neutron ray measuring instrument 51 and the second neutron ray measuring instrument 52.

In the case of the fourth operation mode of FIG. 12, since the beam monitor 42 can serve as a main neutron ray generation source, it can be said that a state is normal where there is a possibility that the neutron ray is detected by the third neutron ray measuring instrument 53 or the fourth neutron ray measuring instrument 54, while the neutron ray is not detected by the first neutron ray measuring instrument 51 or the second neutron ray measuring instrument 52. Therefore, in the fourth operation mode, the upper limit values of the first neutron ray measuring instrument 51 and the second neutron ray measuring instrument 52 may be set to be low (for example, near a background noise level), and the upper limit values of the third neutron ray measuring instrument 53 and the fourth neutron ray measuring instrument 54 may be set to be high. In the fourth operation mode, the beam current may be adjusted while monitoring the neutron ray generated in the beam monitor 42 by using the third neutron ray measuring instrument 53 and the fourth neutron ray measuring instrument 54.

In the case of the fifth operation mode of FIG. 13, since the beam dump 35 can serve as a main neutron ray generation source, it can be said that a state is normal where the neutron ray is not detected by the first neutron ray measuring instrument 51, the second neutron ray measuring instrument 52, or the third neutron ray measuring instrument 53 or a trace amount of the neutron ray can be detected. For example, it can be said that a state is normal where the neutron dose rate that is detected by the first neutron ray measuring instrument 51 or the second neutron ray measuring instrument 52 disposed away from the beam dump 35 is smaller than the neutron dose rate that is detected by the third neutron ray measuring instrument 53 disposed in the vicinity of the beam dump 35. Therefore, in the fifth operation mode, whether the beam is appropriately retreated may be monitored while measuring the neutron ray generated in the beam dump 35 by using the first neutron ray measuring instrument 51, the second neutron ray measuring instrument 52, and the third neutron ray measuring instrument 53. In the fifth operation mode, in a case where the neutron ray is detected by the fourth neutron ray measuring instrument 54, it is considered that some abnormality has occurred in the beam retreat, and the carrying-in and carrying-out of the wafer may be stopped.

In the case of the sixth operation mode of FIG. 14, since the right and left Faraday cups 39L and 39R and the beam monitor 42 can serve as main neutron ray generation sources, whether the ion implantation processing is appropriately performed may be monitored while measuring the neutron ray by using the third neutron ray measuring instrument 53 and the fourth neutron ray measuring instrument 54, as with the fourth operation mode. Even in a case where the neutron ray is not generated in the left and right Faraday cups 39L and 39R or the beam monitor 42, when abnormality occurs in the final energy filter 38 and the high-energy ion beam collides with the AEF electrode pair, there is a possibility that the final energy filter 38 serves as a neutron ray generation source. In a case where the neutron ray is generated in the final energy filter 38 due to the occurrence of abnormality, it is assumed that the neutron dose rate that is detected by the third neutron ray measuring instrument 53 increases. Therefore, in a case where only the neutron dose rate which is measured by the third neutron ray measuring instrument 53 exceeds the upper limit value determined for the sixth operation mode, it is considered that abnormality has occurred in the final energy filter 38, and the ion implantation processing may be stopped.

The central control device 50 may accumulate the measured values of the plurality of neutron ray measuring instruments 51 to 54, and analyze the relationship between the measured values of the measuring instruments in the plurality of operation modes described above or the transition of a time change. For example, the correlation data between the operation modes of the device main body 58 and the measured values of the plurality of neutron ray measuring instruments 51 to 54 in a specific operation mode may be accumulated, and the state of each device configuring the device main body 58 may be estimated based on the accumulated correlation data. As the state of each device, for example, whether or not the device is in a situation where maintenance is required at the current time may be estimated, or the time when maintenance is required in the future may be estimated. The neutron dose rate that can be generated in a neutron ray generation source can increase as the amount of boron accumulated in the neutron ray generation source increases due to the long-term use of the device. Therefore, it is possible to estimate the necessity or timing of maintenance by analyzing an increasing tendency of the neutron dose rate that is measured by the measuring instrument.

The central control device 50 may detect abnormality of at least one measuring instrument itself, based on the operation mode of the device main body 58 and the measured values of the plurality of neutron ray measuring instruments 51 to 54 in a specific operation mode. In general, in order to detect abnormality of the neutron ray measuring instrument itself, it is necessary to dispose a plurality of neutron ray measuring instruments at the same position and measure the neutron ray under the same condition. However, in a case where it is necessary to measure the neutron ray at a plurality of locations due to the presence of a plurality of neutron ray generation sources as in the present embodiment, a significant increase in cost is caused by disposing a plurality of neutron ray measuring instruments at each of the plurality of locations. Therefore, in the present embodiment, abnormality of at least one neutron ray measuring instrument itself may be detected based on the measured values of the plurality of neutron ray measuring instruments 51 to 54 which are disposed at different locations.

In each of the operation modes described above, a location that can serve as a main neutron ray generation source is determined for each operation mode, and a distance from the neutron ray generation source to each of the neutron ray measuring instruments 51 to 54 is also fixed. Therefore, the ratio of the measured values of the neutron ray measuring instruments 51 to 54 in a specific operation mode is almost constant. Therefore, in a case where there is a measured value deviating from the ratio of the measured values of the neutron ray measuring instruments 51 to 54 determined for each operation mode, it is possible to detect abnormality of the measuring instrument itself or to estimate the measuring instrument in which abnormality has occurred. In addition, the measuring instrument in which abnormality has occurred may be estimated by calculating and comparing the ratio of the measured values of the neutron ray measuring instruments 51 to 54 in the plurality of operation modes.

According to the present embodiment, a location that can serve as a neutron ray generation source is estimated in accordance with the operation mode. Therefore, the neutron ray in the device can be appropriately monitored by using the neutron ray measuring instruments 51 to 54 disposed at a plurality of positions (for example, four positions) smaller than the number of assumed neutron ray generation sources (for example, eight positions). That is, the number of the neutron ray measuring instruments can be reduced compared to a case where the neutron ray measuring instrument is disposed to correspond to each of the plurality of neutron ray generation sources in a one-to-one manner, and an increase in cost due to disposition of a large number of neutron ray measuring instruments can be suppressed.

In the embodiment described above, a case where a plate-shaped or block-shaped neutron ray scattering member is mounted on the device main body 58 or the casing 60 has been described. In a modification example, a granular, gel-like, or paste-like neutron ray scattering member may be provided. For example, a surface or a gap of the device main body 58 or the casing 60 may be coated or filled with a gel-like or paste-like neutron ray scattering member. Alternatively, the cavity portion in the support structure of the device main body 58 or the casing 60 may be filled with a granular neutron ray scattering member.

An aspect of the present embodiment is as follows.

### Aspect 1-1

An ion implanter includes:
a device main body that includes a plurality of units that are disposed along a beamline through which an ion beam is transported, a substrate transferring/processing unit that is disposed on the most downstream side of the beamline, and a neutron ray generation source in which a neutron ray can be generated due to collision of a high-energy ion beam;
a casing that at least partially surrounds the device main body; and
a neutron ray scattering member that is disposed at a position into which a neutron ray that is outgone from the neutron ray generation source in a direction in which a distance from the neutron ray generation source to the casing is equal to or smaller than a predetermined value can be incident.

### Aspect 1-2

In the ion implanter according to Aspect 1-1, the neutron ray scattering member includes a first neutron ray scattering member that is disposed at a position into which a neutron ray that is outgone from the neutron ray generation source in a first direction in which a distance from the neutron ray generation source to the casing is a first distance can be incident, and a second neutron ray scattering member that is disposed at a position into which a neutron ray that is outgone from the neutron ray generation source in a second direction in which a distance from the neutron ray generation source to the casing is a second distance larger than the first distance can be incident, and that has a smaller thickness than the first neutron ray scattering member.

### Aspect 1-3

In the ion implanter according to Aspect 1-1 or 1-2, the neutron ray scattering member is disposed at a position into which a neutron ray that is outgone from the neutron ray generation source in a first direction in which a distance from the neutron ray generation source to the casing is a first distance can be incident, and is not disposed at a position into which a neutron ray that is outgone from the neutron ray generation source in a third direction in which a distance from the neutron ray generation source to the casing is a third distance larger than the first distance can be incident.

### Aspect 1-4

In the ion implanter according to any one of Aspects 1-1 to 1-3, the neutron ray generation source is at least one of a slit, a beam monitor, and a beam dump that are provided in the beamline.

### Aspect 1-5

In the ion implanter according to any one of Aspects 1-1 to 1-4, at least a part of the neutron ray scattering member is mounted on the casing.

### Aspect 1-6

In the ion implanter according to Aspect 1-5, at least a part of the neutron ray scattering member is mounted on a door provided at the casing.

### Aspect 1-7

In the ion implanter according to any one of Aspects 1-1 to 1-6, at least a part of the neutron ray scattering member is mounted on at least one of the device main body and a support structure of the device main body.

### Aspect 1-8

In the ion implanter according to any one of Aspects 1-1 to 1-7, the neutron ray scattering member is not mounted on a part of the casing that is disposed along a partial section of the beamline.

### Aspect 1-9

In the ion implanter according to Aspect 1-8, the plurality of units include a beam acceleration unit that accelerates an ion beam extracted from an ion source to generate the high-energy ion beam, and a beam transport unit that transports the high-energy ion beam toward the substrate transferring/processing unit, and
the neutron ray scattering member is at least partially mounted on a part of the casing that is disposed along the beam transport unit, and is not at least partially mounted on a part of the casing that is disposed along the beam acceleration unit.

### Aspect 1-10

In the ion implanter according to Aspect 1-9, the plurality of units further include a beam deflection unit that connects the beam acceleration unit and the beam transport unit,
the beamline is configured in a U-shape by the linear beam acceleration unit, the curved beam deflection unit, and the linear beam transport unit, and
the neutron ray scattering member is at least partially mounted on a part of the casing that is disposed along the beam deflection unit.

### Aspect 1-11

In the ion implanter according to any one of Aspects 1-1 to 1-10, the substrate transferring/processing unit includes an implantation processing chamber in which implantation processing of irradiating a wafer with the high-energy ion beam is performed, a load port in which a wafer container capable of accommodating a plurality of wafers is placed, and a substrate transfer device that transfers the wafer between the implantation processing chamber and the wafer container,
the casing has a wafer container transfer port configured such that the wafer container can pass in a vertical direction vertically above the load port, and
the neutron ray scattering member is disposed so as not to hinder transport of the wafer container at the wafer container transfer port.

### Aspect 1-12

In the ion implanter according to Aspect 1-11, some of the neutron ray scattering members are disposed to overlap each other in the horizontal direction with the wafer container transport port interposed therebetween.

### Aspect 1-13

In the ion implanter according to Aspect 1-11 or 1-12, the casing includes an entrance that is provided on a front side of the load port, one hinged door that closes the right end or left end of the entrance, and two slide doors that close the remaining portion of the entrance that is not closed by the hinged door, and
the neutron ray scattering member is mounted on both the hinged door and the slide door.

### Aspect 1-14

In the ion implanter according to Aspect 1-11 or 1-12, the casing includes an entrance that is provided on a front side of the load port, two hinged doors that close the right end and left end of the entrance, and one slide door that closes the center of the entrance that is not closed by the two hinged doors, and
the neutron ray scattering member is mounted on both the hinged door and the slide door.

### Aspect 1-15

In the ion implanter according to any one of Aspects 1-1 to 1-14, the casing includes a side wall portion that is provided on the side of the device main body, a ceiling portion that is provided vertically above the device main body, and a floor portion that is provided vertically below the device main body, and
each of the side wall portion, the ceiling portion, and the floor portion has a location where the neutron ray scattering member is mounted and a location where the neutron ray scattering member is not mounted.

### Aspect 1-16

In the ion implanter according to any one of Aspects 1-1 to 1-15, the neutron ray scattering member is made of a material having a hydrogen atom content in a range of 0.08 g/cm³ to 0.15 g/cm³.

### Aspect 1-17

In the ion implanter according to any one of Aspects 1-1 to 1-16, the neutron ray scattering member contains polyolefin.

### Aspect 1-18

In the ion implanter according to Aspect 1-17, the neutron ray scattering member further contains boron atoms.

### Aspect 1-19

In the ion implanter according to any one of Aspects 1-1 to 1-18, at least a part of the neutron ray scattering member is plate-shaped or block-shaped.

### Aspect 1-20

In the ion implanter according to Aspect 1-19, a non-combustible sheet is mounted on a surface of the plate-shaped or block-shaped neutron ray scattering member.

### Aspect 1-21

In the ion implanter according to any one of Aspects 1-1 to 1-20, at least a part of the neutron ray scattering member is granular, gel-like, or paste-like.

### Aspect 1-22

In the ion implanter according to any one of Aspects 1-1 to 1-21, the ion implanter further includes an X-ray shielding member that is mounted on the casing.

### Aspect 1-23

In the ion implanter according to any one of Aspects 1-1 to 1-22, the high-energy ion beam includes a boron ion having energy of 4 MeV or higher.

Another aspect of the present embodiment is as follows.

### Aspect 2-1

An ion implanter includes:
a plurality of devices that are disposed along a beamline along which an ion beam is transported;
a plurality of neutron ray measuring instruments that are disposed at a plurality of positions in the vicinity of the beamline to measure a neutron ray that can be generated at a plurality of locations of the beamline due to a collision of a high-energy ion beam; and
a control device that monitors at least one of the plurality of devices, based on a measured value of at least one neutron ray measuring instrument among the plurality of neutron ray measuring instruments.

### Aspect 2-2

In the ion implanter according to Aspect 2-1, the control device estimates a position of the neutron ray generation source of at least one location of the beamline, based on the measured values of the plurality of neutron ray measuring instruments.

### Aspect 2-3

In the ion implanter according to Aspect 2-1 or 2-2, the control device estimates the intensity of the neutron ray that is emitted from the neutron ray generation source of at least one location of the beamline, based on the measured values of the plurality of neutron ray measuring instruments.

### Aspect 2-4

In the ion implanter according to any one of Aspects 2-1 to 2-3, at least one of the plurality of neutron ray measuring instruments is disposed in the vicinity of at least one of a slit, a beam monitor, and a beam dump which are provided in the beamline.

### Aspect 2-5

In the ion implanter according to any one of Aspects 2-1 to 2-4, the control device detects abnormality of at least one of the plurality of devices, based on information about the operation modes of the plurality of devices and the measured value of at least one of the neutron ray measuring instruments in a specific operation mode.

### Aspect 2-6

In the ion implanter according to Aspect 2-5, the control device changes the operation condition of at least one of the plurality of devices such that the measured value becomes equal to or smaller than the reference value, in a case where the measured value of at least one neutron ray measuring instrument exceeds the reference value that is determined to correspond to the specific operation mode.

### Aspect 2-7

In the ion implanter according to any one of Aspects 2-1 to 2-6, the control device accumulates correlation data between the operation modes of the plurality of devices and the measured values of the plurality of neutron ray measuring instruments in a specific operation mode, and estimates a device that needs maintenance among the plurality of devices, based on the accumulated correlation data.

### Aspect 2-8

In the ion implanter according to Aspect 2-7, the control device estimates a maintenance timing of at least one of the plurality of devices, based on the accumulated correlation data.

### Aspect 2-9

In the ion implanter according to any one of Aspects 2-1 to 2-8, the control device detects abnormality of at least one of the plurality of devices, based on information about the operation modes of the plurality of devices and the measured values of at least two or more neutron ray measuring instruments in a specific operation mode.

### Aspect 2-10

In the ion implanter according to any one of Aspects 2-1 to 2-9, the plurality of devices include a beam accelerator that accelerates an ion beam extracted from an ion source to generate the high-energy ion beam, and an energy analyzing device that is disposed downstream of the beam accelerator, and
the control device adjusts at least one of energy and a beam current of the ion beam that is output from the energy analyzing device, while monitoring a neutron ray that can be generated in at least one of the beam accelerator and the energy analyzing device by using at least two or more neutron ray measuring instruments.

### Aspect 2-11

In the ion implanter according to Aspect 2-10, the plurality of neutron ray measuring instruments include a first measuring instrument that is disposed in the vicinity of a slit that is provided at an outlet of the beam accelerator, and a second measuring instrument that is disposed in the vicinity of a slit and a beam monitor that are provided at an outlet of the energy analyzing device, and
the control device monitors the neutron ray that is generated in at least one of the beam accelerator and the energy analyzing device by using the first measuring instrument and the second measuring instrument.

### Aspect 2-12

In the ion implanter according to Aspect 2-11, the control device monitors the neutron ray that can be generated downstream of the beamline with respect to the energy analyzing device by using the first measuring instrument and the second measuring instrument.

### Aspect 2-13

In the ion implanter according to any one of Aspects 2-1 to 2-12, the plurality of devices include a beam deflection device that applies at least one of an electric field and a magnetic field to the ion beam and retreats the ion beam toward a beam dump that is provided away from the beamline, and
the control device monitors the neutron ray that can be generated in the beam dump at the time of the retreat of the ion beam by the beam deflection device by using at least two or more neutron ray measuring instruments.

### Aspect 2-14

In the ion implanter according to any one of Aspects 2-1 to 2-13, the plurality of neutron ray measuring instruments include a third measuring instrument that is disposed on the upstream side of a beam monitor that is provided in the vicinity of an implantation position where a wafer to be irradiated with the ion beam is disposed, and a fourth measuring instrument that is disposed on the downstream side of the beam monitor that is provided in the vicinity of the implantation position, and
the control device monitors the neutron ray that can be generated in the beam monitor that is provided in the vicinity of the implantation position by using the third measuring instrument and the fourth measuring instrument.

### Aspect 2-15

In the ion implanter according to any one of Aspects 2-1 to 2-14, the control device detects abnormality of at least one neutron ray measuring instrument itself, based on information about the operation modes of the plurality of devices and the measured values of the plurality of neutron ray measuring instruments in a specific operation mode.

### Aspect 2-16

The ion implanter according to any one of Aspects 2-1 to 2-15 further includes a casing that surrounds the plurality of devices and the plurality of neutron ray measuring instruments,
in which the control device estimates a neutron dose rate outside the casing, based on the measured values of the plurality of neutron ray measuring instruments.

### Aspect 2-17

In the ion implanter according to Aspect 2-16, the control device estimates the neutron dose rate outside the casing, based on the disposition of at least one of the neutron ray scattering member that is included in the casing and the neutron ray scattering member that is disposed in the vicinity of the beamline.

### Aspect 2-18

In the ion implanter according to Aspect 2-16 or 2-17, the control device changes the operation condition of at least one of the plurality of devices such that the neutron dose rate outside the casing decreases in a case where the estimated neutron dose rate outside the casing exceeds a predetermined upper limit value.

### Aspect 2-19

In the ion implanter according to any one of Aspects 2-16 to 2-18, the control device estimates a dose rate distribution of the neutron ray inside the casing, based on the measured values of the plurality of neutron ray measuring instruments.

### Aspect 2-20

In the ion implanter according to any one of Aspects 2-1 to 2-19, the high-energy ion beam contains a boron (B) ion having energy of 4 MeV or higher.

### Aspect 2-21

An ion implantation method includes:
measuring neutron rays that can be generated at a plurality of locations of a beamline in which an ion beam is transported due to a collision of a high-energy ion beam, by using a plurality of neutron ray measuring instruments that are disposed at a plurality of positions in the vicinity of the beamline; and
monitoring at least one of a plurality of devices that are disposed along the beamline, based on a measured value of at least one neutron ray measuring instrument among the plurality of neutron ray measuring instruments.

Hereinafter, the method for monitoring a neutron ray will be further described in detail. As described above, the dose rate of the neutron ray that can be generated in the ion implanter 100 is not so large and can be a value close to the detection limit of a general neutron ray measuring instrument. In addition, the neutron dose rates that are measured by the neutron ray measuring instruments 51 to 54 may be different depending on, for example, the plurality of operation modes shown in FIGS. 9 to 14. Further, the neutron dose rate that can be generated in the neutron ray generation source increases as the amount of boron accumulated in the vicinity of the surface of a portion serving as a neutron ray generation source increases due to the long-term use of the device. Therefore, it is not easy to confirm the soundness of the measurement of whether or not there is abnormality in the neutron ray measuring instruments 51 to 54, based on only the measured values of the neutron dose rate, which are measured by the neutron ray measuring instruments 51 to 54.

Therefore, in the present embodiment, the current neutron dose rate is estimated using the time-series data of the measured values of the neutron dose rate measured in the past, and the current measured value and the estimated value of the neutron dose rate are compared with each other to determine the validity of the current measured value of the neutron dose rate. In other words, a reference value for evaluating the validity of the measured value of the current neutron dose rate is determined based on the trend of the neutron dose rate so far, and the soundness of the measurement of whether there is any abnormality in the neutron ray measuring instruments 51 to 54 is checked using the reference value based on the trend. In the present embodiment, since the reference value is dynamically changed based on the trend, the soundness of the measurements of the neutron ray measuring instruments 51 to 54 can be more appropriately checked.

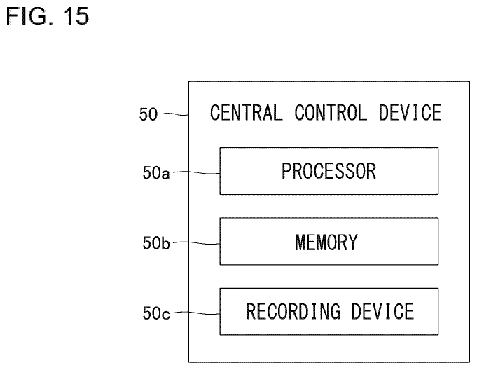

FIG. 15 is a diagram schematically showing a configuration of the central control device 50. The central control device 50 includes a processor 50a such as a central processing unit (CPU), a memory 50b such as a read only memory (ROM) or a random access memory (RAM), and a recording device 50c such as a hard disk drive (HDD) or a solid state drive (SSD).

For example, the central control device 50 cause the processor 50a to execute a program stored in the memory 50b to control the overall operation of the ion implanter 100 in accordance with the program. The processor 50a may execute a program stored in any storage device different from the memory 50b, may execute a program acquired from any recording medium by a reading device, or may execute a program acquired via a network. The memory 50b in which the program is stored may be a volatile memory such as a dynamic random access memory (DRAM), or may be a non-volatile memory such as an electrically erasable programmable read-only memory (EEPROM), a flash memory, a magnetic resistance memory, a resistance change type memory, or a ferroelectric memory. The non-volatile memory, the magnetic recording medium such as a magnetic tape and a magnetic disk, and the optical recording medium such as an optical disk are examples of a non-transitory and tangible computer readable storage medium.

Various functions that are provided by the central control device 50 may be realized by a single device including the processor 50a and the memory 50b, or may be realized by cooperation of a plurality of devices each including the processor 50a and the memory 50b. The recording device 50c records data indicating the operation results of the ion implanter 100. The recording device 50c may be provided in the central control device 50, or may be provided as an external device separate from the central control device 50.

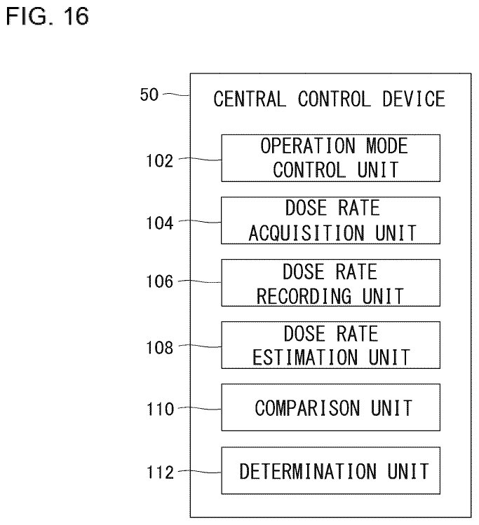

FIG. 16 is a block diagram schematically showing a functional configuration of the central control device 50. The central control device 50 includes an operation mode control unit 102, a dose rate acquisition unit 104, a dose rate recording unit 106, a dose rate estimation unit 108, a comparison unit 110, and a determination unit 112. Each functional block shown in FIG. 16 is realized by causing the processor 50a to execute the program stored in the memory 50b.

The operation mode control unit 102 controls the operation of the device main body 58 according to the operation mode. For example, the operation mode control unit 102 selects at least one of the plurality of operation modes included in the ion implanter 100, and operates the device main body 58 in the selected operation mode. Examples of the plurality of operation modes are the first operation mode to the sixth operation mode shown in FIGS. 9 to 14.

In a case where the device main body 58 operates in any one of the plurality of operation modes, the ion beam that is transported along the beamline BL is at least partially incident into at least one of the plurality of portions inside the ion implanter 100. Here, the plurality of portions into which the ion beam is at least partially incident are at least some of the surfaces of the slit, the beam monitor, the beam dump, and the like, which are members that can serve as neutron ray generation sources described above. Specific examples of the plurality of members are the beam profile slit 23, the energy analyzing slit 27, the first Faraday cup 28, the second Faraday cup 31, the beam dump 35, the left and right Faraday cups 39L and 39R, and the beam monitor 42. However, there is no limitation to these.

In at least one of the plurality of operation modes, at least one of the plurality of portions is disposed on the beamline BL by using a driving device, and the ion beam is at least partially blocked by at least one of the plurality of portions. The driving device is configured to change the position of at least one of a plurality of portions.

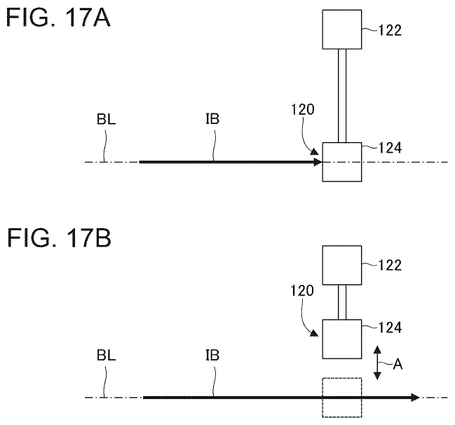

FIGS. 17A and 17B are diagrams schematically showing a driving device 122 that changes the position of a portion 120 into which the ion beam IB is at least partially incident. The driving device 122 is configured to change the position of a member 124 having the portion 120 into which the ion beam IB is partially incident. The driving device 122 may change the position of the portion 120 between a state where the portion 120 is inserted into the beamline BL as shown in FIG. 17A and a state where the portion 120 is retreated from the beamline BL as shown in FIG. 17B. The driving device 122 may change a position or a range into which an ion beam IB is incident in the portion 120 by moving the portion 120 in a direction intersecting the beamline BL (for example, a direction of an arrow A).

For example, in the first operation mode described above, the beam profile slit 23 is inserted into the beamline BL by the driving device, and the ion beam is at least partially blocked by the beam profile slit 23. For example, in the first operation mode described above, the slit width of the energy analyzing slit 27 is changed by the driving device, and the ion beam is at least partially blocked by the energy analyzing slit 27. In the first operation mode or the second operation mode described above, the first Faraday cup 28 is inserted into the beamline BL by the driving device, and the ion beam is at least partially blocked by the first Faraday cup 28. In the third operation mode described above, the second Faraday cup 31 is inserted into the beamline BL, and the ion beam is at least partially blocked by the second Faraday cup 31.

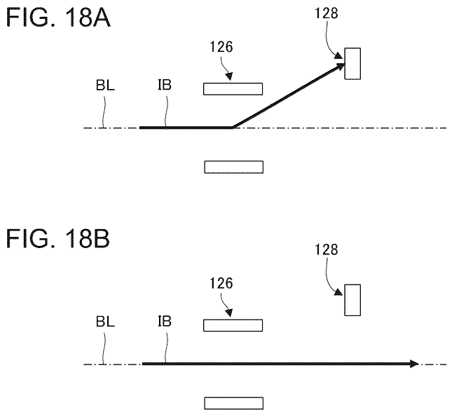

In at least one of the plurality of operation modes, the ion beam is deflected by using a deflection device, so that the ion beam is incident into at least one of the plurality of portions provided away from the beamline BL. FIGS. 18A and 18B are diagrams schematically showing a deflection device 126 that deflects the ion beam IB. The deflection device 126 is configured to apply at least one of an electric field and a magnetic field to deflect the trajectory of the ion beam IB. The deflection device 126 may be configured to switch between a state where the ion beam IB is incident into a portion 128 provided away from the beamline BL as shown in FIG. 18A and a state where the ion beam IB is not incident into the portion 128 provided away from the beamline BL as shown in FIG. 18B. Specific examples of the deflection device 126 include the energy analyzing electromagnet 24, the bending electromagnet 30, the beam scanner 34, the beam parallelizer 36, the final energy filter 38, and the like. However, there is no limitation to these.

For example, in the first operation mode described above, the ion beam is deflected by the energy analyzing electromagnet 24, and the ion beam is incident into the energy analyzing slit 27 provided away from the beamline BL. For example, in the fifth operation mode described above, the ion beam is deflected by using the beam scanner 34, so that the ion beam is incident into the beam dump 35 provided away from the beamline BL. For example, in the sixth operation mode described above, the ion beam is deflected (more specifically, performs reciprocating scanning) by using the beam scanner 34, so that the ion beam is incident into the left and right Faraday cups 39L and 39R provided away from the beamline BL.

In at least one of the plurality of operation modes, the ion beam may be at least partially incident into the first portion, and the ion beam may be at least partially incident into the second portion located on the downstream side of the beamline BL with respect to the first portion. Each of the first portion and the second portion is any of the plurality of portions. For example, in the first operation mode described above, the ion beam is at least partially incident into the beam profile slit 23, and the ion beam is at least partially incident into the energy analyzing slit 27 or the first Faraday cup 28 located on the downstream side of the beam profile slit 23.

Returning to FIG. 16, the dose rate acquisition unit 104 acquires the measured values of the neutron dose rate, which are measured by the plurality of neutron ray measuring instruments 51 to 54. The dose rate acquisition unit 104 may acquire the measured values of the neutron dose rate, which are measured by the plurality of neutron ray measuring instruments 51 to 54 in each of the plurality of operation modes. The dose rate acquisition unit 104 may acquire twenty-four measured values which are measured by the neutron ray measuring instruments 51 to 54 disposed at four measurement positions in each of the six operation modes.

Each of the plurality of neutron ray measuring instruments 51 to 54 is disposed at a corresponding predetermined position (or a predetermined measurement position). For example, the first neutron ray measuring instrument 51 is disposed at a first position (or a first measurement position), the second neutron ray measuring instrument 52 is disposed at a second position (or a second measurement position), the third neutron ray measuring instrument 53 is disposed at a third position (or a third measurement position), and the fourth neutron ray measuring instrument 54 is disposed at a fourth position (or a fourth measurement position).

The measurement positions where the plurality of neutron ray measuring instruments 51 to 54 are disposed are outside the device main body 58 and inside the casing 60. The device main body 58 includes a vacuum chamber that surrounds the beamline BL, and the plurality of neutron ray measuring instruments 51 to 54 are disposed outside the vacuum chamber. At least one of the plurality of neutron ray measuring instruments 51 to 54 is located inside a curved portion extending in an arc shape of the beamline BL. The curved portion extending in an arc shape of the beamline BL is, for example, the beam deflection unit 16. For example, the first neutron ray measuring instrument 51 and the second neutron ray measuring instrument 52 are disposed inside the curved portion that is configured by the beam deflection unit 16.

In a certain embodiment, the dose rate acquisition unit 104 may acquire a first measured value that is measured at a predetermined position (for example, the first neutron ray measuring instrument 51) in the first operation mode, and a second measured value that is measured at the predetermined position (for example, the first neutron ray measuring instrument 51) in the second operation mode. In a certain embodiment, the dose rate acquisition unit 104 may acquire a first measured value that is measured at the first position (for example, the first neutron ray measuring instrument 51) in the first operation mode, and a second measured value that is measured at the second position (for example, the second neutron ray measuring instrument 52) in the first operation mode. In a certain embodiment, the dose rate acquisition unit 104 may acquire a first measured value that is measured at the first position (for example, the first neutron ray measuring instrument 51) in the first operation mode, a second measured value that is measured at the second position (for example, the second neutron ray measuring instrument 52) in the first operation mode, a third measured value that is measured at the first position (for example, the first neutron ray measuring instrument 51) in the second operation mode, and a fourth measured value that is measured at the second position (for example, the second neutron ray measuring instrument 52) in the second operation mode.

The dose rate recording unit 106 records the measured value of the neutron dose rate acquired by the dose rate acquisition unit 104 in association with the beam condition of the ion beam at the time of measurement, the operation mode of the device main body 58, the measurement position, and the measurement time. Here, the beam condition of the ion beam includes the ion species, the energy, and the beam current of the ion beam. The beam condition may further include a transport parameter for controlling at least one of a beam central trajectory, a beam size, and a beam shape of the ion beam. The transport parameter can be referred to as an operation parameter for controlling the operation of various devices of the device main body 58 for transporting an ion beam satisfying a predetermined beam condition. The dose rate recording unit 106 records, for example, the acquired measured value of the neutron dose rate as time-series data, and allows a time change (that is, a trend) of the neutron dose rate to be analyzed posteriorly, based on the time-series data.

The dose rate recording unit 106 may record only the measured value of the neutron dose rate that is measured in a case where the high-energy ion beam capable of generating the neutron ray is transported. For example, the dose rate recording unit 106 may record only the measured value of the neutron dose rate that is measured in a case where the ion species is a boron ion and the beam energy is high energy within a predetermined energy range of 3.7 MeV or higher and 10 MeV or lower. In other words, the dose rate recording unit 106 does not need to record the measured value of the neutron dose rate that is measured in a case where the ion species is other than boron or in a case where the beam energy is lower than 3.7 MeV.

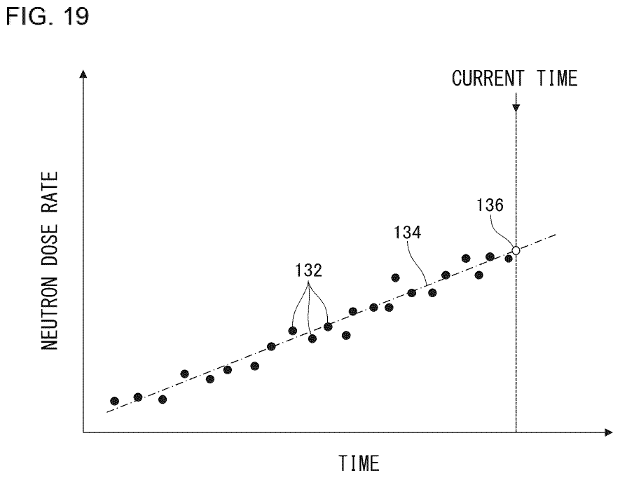

The dose rate estimation unit 108 estimates the neutron dose rate by using the time-series data recorded in the recording device 50c by the dose rate recording unit 106. FIG. 19 is a graph schematically showing a method for estimating a neutron dose rate. FIG. 19 schematically shows the time-series data of the neutron dose rate that is recorded in the recording device 50c. The time-series data includes a plurality of measured values 132 of the neutron dose rate measured at different times in the past. The dose rate estimation unit 108 disposes the plurality of measured values 132 in the order of time and determines a function 134 indicating a trend of the plurality of measured values 132. In the example shown in FIG. 19, the function 134 is an approximate straight line for the plurality of measured values 132. However, the function 134 is not limited to the straight line and may be a polynomial of any degree (for example, a sixth degree), an exponential function, or a logarithmic function. The function 134 may be a moving average line of the plurality of measured values 132. The dose rate estimation unit 108 sets an intersection point 136 between the determined function 134 and the current time as an estimated value of the current neutron dose rate. The time-series data of the neutron dose rate that changes with the elapse of time corresponds to a change in an accumulation state in which a specific element (for example, boron) causing a nuclear reaction is accumulated in a portion serving as a neutron ray generation source.

The dose rate estimation unit 108 estimates the neutron dose rate according to a combination of the operation mode of the ion implanter 100, the beam condition of the ion beam, and the measurement position. Since the neutron dose rate varies depending on the accumulation state of a specific element (for example, boron), the operation mode, the beam condition, and the measurement position, the dose rate estimation unit 108 estimates the neutron dose rate in consideration of these. For example, the dose rate estimation unit 108 calculates an estimated value of the current neutron dose rate by using a plurality of measured values in which the combination of the operation mode, the beam condition, and the measurement position matches, in the time-series data recorded in the recording device 50c. For example, when it is assumed that the high-energy ion beam containing the boron ions is transported in the first operation mode, the estimated value of the neutron dose rate estimated at the first position (for example, the first neutron ray measuring instrument 51) is estimated using a plurality of measured values measured in the past at the first position (for example, the first neutron ray measuring instrument 51) when the high-energy ion beam containing the boron ions is transported in the first operation mode.

The dose rate estimation unit 108 may calculate an estimated value of the neutron dose rate by using only the past measured value in which all of the ion species, the energy, and the beam current of the beam condition match. The dose rate estimation unit 108 may calculate an estimated value of the neutron dose rate by using the past measured value in which a part of the beam condition does not match. The dose rate estimation unit 108 may calculate an estimated value of the neutron dose rate by using the past measured value in which the ion species and the energy are the same but the beam current is not the same. In this case, an estimated value of the neutron dose rate may be calculated using a value obtained by correcting the past measured value, based on a difference in the beam currents. For example, a correlation between the neutron dose rate and the magnitude of the beam current may be calculated in advance, and the neutron dose rate may be estimated using a value obtained by correcting the past measured value, based on the correlation. The dose rate estimation unit 108 may calculate an estimated value of the neutron dose rate by using the past measured value in which the ion species and the beam current are the same but the energy is not the same. In this case, an estimated value of the neutron dose rate may be calculated using a value obtained by correcting the past measured value, based on a difference in energy. For example, a correlation between the neutron dose rate and the magnitude of the energy may be calculated in advance, and the neutron dose rate may be estimated using a value obtained by correcting the past measured value, based on the correlation. The dose rate estimation unit 108 may calculate an estimated value of the neutron dose rate by using the past measured value in which the ion species is the same but the energy and the beam current are not the same. In this case, an estimated value of the neutron dose rate may be calculated using a value obtained by correcting the past measured value, based on a difference between the energy and the beam current. For example, a correlation between the neutron dose rate and the magnitudes of the energy and the beam current may be calculated in advance, and the neutron dose rate may be estimated using a value obtained by correcting the past measured value, based on the correlation.

The comparison unit 110 compares the current measured value of the neutron dose rate acquired by the dose rate acquisition unit 104 with the estimated value of the neutron dose rate estimated by the dose rate estimation unit 108. The comparison unit 110 may determine whether or not the difference between the current measured value and the estimated value exceeds a predetermined threshold, and may output an alert in a case where the difference exceeds the predetermined threshold. The predetermined threshold may be a fixed value that does not depend on the magnitude of the estimated value, or may be a value obtained by multiplying the estimated value by a predetermined ratio. The predetermined threshold may be determined based on a variation in the past measured values used for the calculation of the estimated value, or may be determined using a statistical value (for example, a standard deviation) indicating a variation in the plurality of measured values 132 with respect to the function 134 shown in FIG. 19.

The comparison unit 110 may compare the plurality of current measured values of the neutron dose rate measured in the plurality of operation modes with the plurality of estimated values of the neutron dose rate estimated in the plurality of operation modes. In a certain embodiment, the comparison unit 110 may compare the first measured value measured at the first position (for example, the neutron ray measuring instrument 51) in the first operation mode with the first estimated value estimated at the first position in the first operation mode, and compare the second measured value measured at the first position (for example, the neutron ray measuring instrument 51) in the second operation mode with the second estimated value estimated at the first position in the second operation mode. In this embodiment, the comparison unit 110 may output an alert in a case where at least one of the difference between the first measured value and the first estimated value and the difference between the second measured value and the second estimated value exceeds a predetermined threshold. In this embodiment, the predetermined threshold may be commonly set for the first estimated value and the second estimated value, or may be individually set for the first estimated value and the second estimated value.

The comparison unit 110 may compare the plurality of current measured values of the neutron dose rate, which are measured by the plurality of neutron ray measuring instruments 51 to 54, with the plurality of estimated values of the neutron dose rate, which are estimated at the plurality of measurement positions. In a certain embodiment, the comparison unit 110 may compare the first measured value measured at the first position (for example, the neutron ray measuring instrument 51) in the first operation mode with the first estimated value estimated at the first position in the first operation mode, and may compare the second measured value measured at the second position (for example, the second neutron ray measuring instrument 52) in the first operation mode and with second estimated value estimated at the second position in the first operation mode. In this embodiment, the comparison unit 110 may output an alert in a case where at least one of the difference between the first measured value and the first estimated value and the difference between the second measured value and the second estimated value exceeds a predetermined threshold. In this embodiment, the predetermined threshold may be commonly set for the first estimated value and the second estimated value, or may be individually set for the first estimated value and the second estimated value.

The comparison unit 110 may compare the plurality of current measured values of the neutron dose rate, which are measured by the plurality of neutron ray measuring instruments 51 to 54 in the plurality of operation modes, with the plurality of estimated values of the neutron dose rate, which are estimated at the plurality of measurement positions in the plurality of operation modes. In a certain embodiment, the comparison unit 110 may compare the first measured value which is measured at the first position (for example, the neutron ray measuring instrument 51) in the first operation mode with the first estimated value which is estimated at the first position in the first operation mode, compare the second measured value which is measured at the second position (for example, the second neutron ray measuring instrument 52) in the first operation mode with the second estimated value which is estimated at the second position in the first operation mode, compare the third measured value which is measured at the first position (for example, the neutron ray measuring instrument 51) in the second operation mode with the third estimated value which is estimated at the first position in the second operation mode, and compare the fourth measured value which is measured at the second position (for example, the second neutron ray measuring instrument 52) in the second operation mode with the fourth estimated value which is estimated at the second position in the second operation mode. In this embodiment, the comparison unit 110 may compare twenty-four measured values which are measured at four positions (for example, the neutron ray measuring instruments 51 to 54) in each of six operation modes with twenty-four estimated values which are measured at four positions in each of the six operation modes. In this embodiment, the comparison unit 110 may output an alert in a case where at least one of the differences between the measured values and the estimated values corresponding to the measured values exceeds a predetermined threshold. In this embodiment, the predetermined threshold may be commonly set for the plurality of estimated values, or may be individually set for the plurality of estimated values.

The comparison unit 110 may determine the validity of the transport parameter included in the beam condition in a case where the difference between the measured values and the estimated values corresponding to the measured values exceeds a predetermined threshold. The comparison unit 110 may compare the current transport parameter set in the device main body 58 at the time of measuring the neutron dose rate with the past transport parameter corresponding to the past measured value recorded in the recording device 50c. The comparison unit 110 may output an alert in a case where a difference between the current transport parameter and the past transport parameter exceeds a predetermined threshold. In this case, as a cause of the current measured value of the neutron dose rate being abnormal, a situation can be estimated in which the ion beam being incident into an unexpected portion due to the difference between the current transport parameter and the past transport parameter and the amount of neutron ray generated changes.

In a case where the current measured value of the neutron dose rate which is acquired by the dose rate acquisition unit 104 exceeds a predetermined reference value, the determination unit 112 may output an alert. In a case where the estimated value of the neutron dose rate which is estimated by the dose rate estimation unit 108 exceeds a predetermined reference value, the determination unit 112 may output an alert. Here, the predetermined reference value is, for example, a management upper limit value of the neutron dose rate. In a case where the alert is output by the determination unit 112, for example, in order to reduce the neutron dose rate, the maintenance of the ion implanter 100 is performed, such as replacing a component including a portion that can serve as a neutron ray generation source, or cleaning the component outside the device.

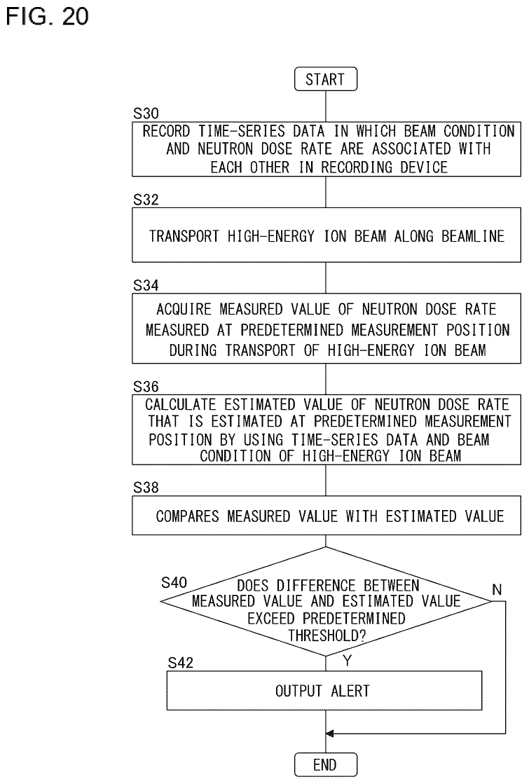

FIG. 20 is a flowchart showing an example of the flow of the method for monitoring a neutron ray according to the embodiment. The processor 50a records the time-series data in which the beam condition and the neutron dose rate are associated with each other in the recording device 50c (S30). The processor 50a controls the operation of the device main body 58 to transport the high-energy ion beam along the beamline BL (S32). The processor 50a acquires the measured value of the neutron dose rate which is measured at a predetermined measurement position during the transport of the high-energy ion beam (S34). The processor 50a calculates the estimated value of the neutron dose rate which is estimated at the predetermined measurement position by using the time-series data recorded in the recording device 50c and the beam condition of the high-energy ion beam currently being transported (S36). The processor 50a compares the measured value with the estimated value (S38), and in a case where a difference between the measured value and the estimated value exceeds a predetermined threshold (Y in S40), the processor 50a outputs an alert (S42). In a case where the difference between the measured value and the estimated value is equal to or smaller than the predetermined threshold (N in S40), the processor 50a skips the processing in S42.

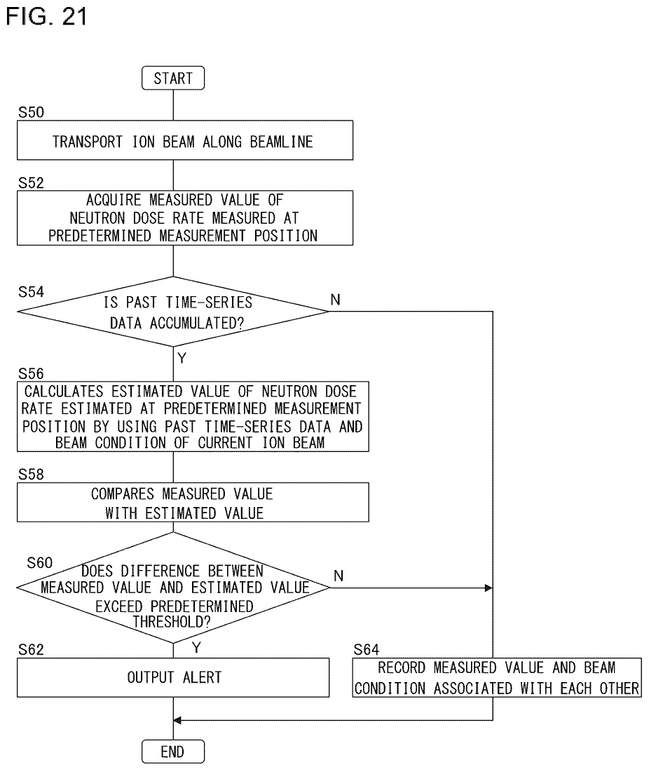

FIG. 21 is a flowchart showing another example of the flow of the method for monitoring a neutron ray according to the embodiment. The processor 50a controls the operation of the device main body 58 to transport the ion beam along the beamline BL (S50). The ion beam that is transported in S50 may be a high-energy ion beam or may be a low-energy ion beam that is not high-energy. The processor 50a acquires the measured value of the neutron dose rate which is measured at a predetermined measurement position during the transport of the ion beam (S52). When the past time-series data is accumulated in the recording device 50c (Y in S54), the processor 50a calculates the estimated value of the neutron dose rate which is estimated at the predetermined measurement position by using the past time-series data and the beam condition of the ion beam currently being transported (S56). The processor 50a compares the measured value with the estimated value (S58), and in a case where a difference between the measured value and the estimated value exceeds a predetermined threshold (Y in S60), the processor 50a outputs an alert (S62). In a case where the difference between the measured value and the estimated value is equal to or smaller than the predetermined threshold (N in S60), the processor 50a associates the measured value of the neutron dose rate with the beam condition of the ion beam currently being transported and records the measured value and the beam condition associated with each other in the recording device 50c (S64). When the past time-series data is not sufficiently accumulated in the recording device 50c to an extent that the neutron dose rate can be estimated (N in S54), the processor 50a skips the processing in S56 to S60 and executes the processing in S64.

Subsequently, a method for reducing the dose rate of the neutron ray that is generated in the ion implanter 100 will be described. When a specific element (for example, boron) that causes a nuclear reaction is accumulated in a portion serving as a neutron ray generation source in association with the operation of the ion implanter 100, the neutron dose rate when a high-energy ion beam is incident into the portion increases. In particular, the neutron dose rate increases as the amount of a specific element present in the vicinity of the surface of the portion serving as a neutron ray generation source increases. Therefore, when the amount of a specific element present in the vicinity of the surface of the portion serving as a neutron ray generation source can be reduced, the neutron dose rate when a high-energy ion beam is incident into the portion can be reduced.

As a method for reducing the amount of a specific element present in the vicinity of the surface of a portion serving as a neutron ray generation source, it is conceivable to replace a component configuring the portion or to remove the component and clean the component outside the device. However, in a case where the maintenance of the ion implanter 100 is performed for the replacement of the component or the cleaning of the component outside the device, the operation of the ion implanter 100 has to be stopped for a certain period of time, which leads to a decrease in the productivity of the ion implanter 100. Therefore, in the present embodiment, the cleaning to reduce the amount of a specific element present in the vicinity of the surface of a portion serving as the neutron ray generation source is performed by a method different from the method for replacing a component and cleaning a component outside the device. Specifically, the amount of a specific element present in the vicinity of the surface of a portion serving as a neutron ray generation source is reduced by irradiating the portion serving as a neutron ray generation source with an ion beam containing an ion species of an element different from the specific element. By irradiating the surface of an irradiation target with an ion beam containing an ion species of an element different from the specific element, it is possible to remove the specific element in the vicinity of the surface of the irradiation target by sputtering or to cover the vicinity of the surface of the irradiation target with an element different from the specific element.

The ion beam for cleaning includes an ion species of an element having a larger atomic number or mass number than a specific element. In a case where the specific element is boron, the ion species of the ion beam that is used for the cleaning is, for example, an ion of phosphorus (P), arsenic (As), argon (Ar), fluorine (F), xenon (Xe), carbon monoxide (CO), or carbon dioxide (CO₂). The ion beam for cleaning may be used exclusively for cleaning, or may also be used for ion implantation processing for the wafer. In other words, the wafer may not be irradiated with the ion beam for cleaning, or may be sequentially irradiated with the ion beam for cleaning. A plurality of wafers included in at least one lot may be irradiated with the ion beam for cleaning.

The ion beam for cleaning is transported to be incident into at least one of a plurality of portions serving as neutron ray generation sources. The ion beam for cleaning may be transported in at least one of the plurality of operation modes described above, may be transported in at least two of the plurality of operation modes, or may be transported in all of the plurality of operation modes. By transporting the ion beam for cleaning in at least one of the plurality of operation modes, at least one of the plurality of portions serving as neutron ray generation sources when transporting the high-energy ion beam in at least one of the plurality of operation modes can be cleaned. For example, by transporting the ion beam for cleaning in the first operation mode, at least one of a plurality of portions serving as neutron ray generation sources when the high-energy ion beam is transported in the first operation mode can be cleaned.

The ion beam for cleaning may be transported in a predetermined cleaning mode. In the cleaning mode, the ion beam for cleaning is transported such that a position or a range into which the ion beam is at least partially incident at the portion to be cleaned is changed. In the cleaning mode, a position or a range into which the ion beam is at least partially incident at the portion to be cleaned is changed by at least one of changing a transport state of the ion beam for cleaning and changing a position of the portion to be cleaned. In this way, it is possible to improve the cleaning efficiency at the portion to be cleaned.

In the cleaning mode, the transport state (for example, at least one of the beam central trajectory, the beam size, and the beam shape) of the ion beam for cleaning may be changed by changing a transport parameter while the position of the portion to be cleaned is fixed. For example, by perform reciprocating scanning of a beam central trajectory of the ion beam in a predetermined direction by using a deflection device, a position into which the ion beam for cleaning is incident at the portion to be cleaned can be reciprocated in the predetermined direction. In addition, a range into which the ion beam for cleaning is incident at the portion to be cleaned can be changed by expanding or contracting the beam size or changing the beam shape by using a quadrupole focusing/defocusing device (Q-lens) or the like.

In the cleaning mode, the position of the portion to be cleaned may be changed by the driving device while the beam central trajectory, the beam size, and the beam shape of the ion beam for cleaning are fixed. For example, by performing reciprocating scanning of the portion to be cleaned in a predetermined direction, a position into which the ion beam for cleaning is incident at the portion to be cleaned can be reciprocated in the predetermined direction. In the cleaning mode, a change in at least one of the beam central trajectory, the beam size, and the beam shape of the ion beam and a change in the position of the portion to be cleaned may be used in combination.

The ion implanter 100 may include a plurality of cleaning modes corresponding to a plurality of operation modes. The operation mode control unit 102 may operate the device main body 58 in accordance with the cleaning mode. Here, the cleaning mode corresponding to a specific operation mode is a cleaning mode for cleaning a portion serving as a neutron ray generation source in the specific operation mode. The cleaning mode corresponding to the specific operation mode may be different from the specific operation mode in that the cleaning mode includes at least one of intentionally changing a transport state of the ion beam for cleaning and intentionally changing a position of the portion to be cleaned, and may be common to the specific operation modes in other aspects. For example, in the first cleaning mode corresponding to the first operation mode of FIG. 9, the ion beam for cleaning is incident into the beam profile slit 23, the energy analyzing slit 27, and the first Faraday cup 28 to clean the beam profile slit 23, the energy analyzing slit 27, and the first Faraday cup 28. The first cleaning mode may be different from the first operation mode in that the first cleaning mode includes at least one of intentionally changing the transport state of the ion beam for cleaning and intentionally changing the positions of the beam profile slit 23, the energy analyzing slit 27, and the first Faraday cup 28.

In a case where the current measured value of the neutron dose rate that is acquired by the dose rate acquisition unit 104 exceeds a predetermined threshold, the ion implanter 100 may transport the ion beam for cleaning and execute cleaning of the portion serving as a neutron ray generation source. In a case where the estimated value of the neutron dose rate that is estimated by the dose rate estimation unit 108 exceeds a predetermined threshold, the ion implanter 100 may transport the ion beam for cleaning and execute cleaning of the portion serving as a neutron ray generation source. Therefore, in a case where at least one of the measured value and the estimated value of the neutron dose rate exceeds a predetermined threshold, the ion implanter 100 may transport the ion beam for cleaning and execute cleaning of the portion serving as a neutron ray generation source. Here, the predetermined threshold may be the same as the reference value, which is the management upper limit value of the neutron dose rate described above, or may be a value lower than the reference value. The predetermined threshold may be, for example, in a range of 10% to 90% of the reference value, or may be 25%, 50%, or 75% of the reference value. The predetermined threshold may be changed in accordance with the operation time from the previous maintenance of the ion implanter 100, and the reference value may be increased as the operation time becomes longer.

In a case where at least one of the plurality of measured values of the neutron dose rate, which are measured at a plurality of measurement positions, exceeds a predetermined threshold, the ion implanter 100 may transport the ion beam for cleaning and execute cleaning of the portion serving as a neutron ray generation source. In a case where at least one of the plurality of estimated values of the neutron dose rate, which are estimated at the plurality of measurement positions, exceeds a predetermined threshold, the ion implanter 100 may transport the ion beam for cleaning and execute cleaning of the portion serving as a neutron ray generation source.

In a case where at least one of the plurality of measured values of the neutron dose rate, which are measured in the plurality of operation modes, exceeds a predetermined threshold, the ion implanter 100 may transport the ion beam for cleaning and execute cleaning of the portion serving as a neutron ray generation source. In a case where at least one of the plurality of estimated values of the neutron dose rate, which are estimated in the plurality of operation modes exceeds a predetermined threshold, the ion implanter 100 may transport the ion beam for cleaning and execute cleaning of the portion serving as a neutron ray generation source. In this case, the ion beam for cleaning may be transported in the operation mode in which the measured value or the estimated value exceeds a predetermined threshold, or the ion beam for cleaning may be transported in the cleaning mode corresponding to the operation mode in which the measured value or the estimated value exceeds a predetermined threshold.

In a case where at least one of the plurality of measured values of the neutron dose rate corresponding to a combination of the plurality of operation modes and the plurality of measurement positions exceeds a predetermined threshold, the ion implanter 100 may transport the ion beam for cleaning and execute cleaning of the portion serving as a neutron ray generation source. In a case where at least one of the plurality of estimated values of the neutron dose rate corresponding to a combination of the plurality of operation modes and the plurality of measurement positions exceeds a predetermined threshold, the ion implanter 100 may transport the ion beam for cleaning and execute cleaning of the portion serving a neutron ray generation source. In this case, the ion beam for cleaning may be transported in the operation mode in which the measured value or the estimated value exceeds a predetermined threshold, or the ion beam for cleaning may be transported in the cleaning mode corresponding to the operation mode in which the measured value or the estimated value exceeds a predetermined threshold.

The ion implanter 100 may transport the high-energy ion beam after transporting the ion beam for cleaning and acquire the measured value of the neutron dose rate after the cleaning. In a case where the measured value after the cleaning exceeds a predetermined threshold, the ion implanter 100 may execute re-cleaning. That is, second cleaning may be executed after first cleaning. The beam condition of the ion beam for the second cleaning may be the same as or may be different from the beam condition of the ion beam for the first cleaning. For example, in a case where arsenic ions are used in the first cleaning, arsenic ions may also be used in the second cleaning, or phosphorus ions, argon ions, or fluorine ions different from the arsenic ions may be used in the second cleaning. In addition, in the second cleaning, the beam current may be increased more than that in the first cleaning, or the energy may be decreased less than that in the first cleaning.

In a case where any of the plurality of measured values of the neutron dose rates corresponding to a combination of the plurality of operation modes and the plurality of measurement positions does not exceed a predetermined threshold, the ion implanter 100 may execute the ion implantation processing by the high-energy ion beam without transporting the ion beam for cleaning. In a case where any of the plurality of estimated values of the neutron dose rate corresponding to a combination of the plurality of operation modes and the plurality of measurement positions does not exceed a predetermined threshold, the ion implanter 100 may execute the ion implantation processing by the high-energy ion beam without transporting the ion beam for cleaning. In this case, at least one wafer may be irradiated with the high-energy ion beam, or a plurality of wafers included in at least one lot may be sequentially irradiated with the high-energy ion beam.

It is known that the dose rate of the neutron ray that is generated by a B-B reaction in which boron and boron collide with each other tends to increase in a case where after boron is accumulated in the vicinity of the surface of the portion that can serve as a neutron ray generation source by transport of a low-energy boron ion beam, a high-energy boron ion beam is transported. Here, an example of the low energy is 0.1 MeV or higher and lower than 3.7 MeV, and an example of the high energy is 3.7 MeV or higher and 10 MeV or lower. In a case of being irradiated with the high-energy boron ion beam, boron is accumulated at a relatively deep position away from the surface of the portion into which the boron ions are incident. On the other hand, in a case of being irradiated with the low-energy boron ion beam, boron is accumulated at a shallow position near the surface of the portion into which the boron ions are incident. Since the B-B reaction is generated at a theoretical energy threshold (for example, 3.7 MeV) or more, the B-B reaction is generated only in the vicinity of the surface into which the high-energy boron ions are incident. The high-energy boron ions are decelerated as they proceed in the depth direction from the surface of the portion into which the boron ions are incident, and the energy thereof becomes smaller than the reaction threshold at a deep position from the surface of the portion into which the boron ions are incident. Therefore, the boron accumulated at the deep position from the surface does not contribute to the generation of the neutron ray.

Therefore, in a case where the transport of the high-energy boron ion beam is scheduled after the transport of the low-energy boron ion beam, it is preferable to reduce the amount of boron present in the vicinity of the surface of the portion that can serve as a neutron ray generation source by transporting the ion beam for cleaning. That is, it is preferable to transport the ion beam for cleaning after the transport of the low-energy boron ion beam and before the transport of the high-energy boron ion beam. The neutron dose rate may be measured or estimated when the high-energy boron ion beam is transported after the transport of the low-energy boron ion beam, and it may be determined whether or not at least one of the measured value and the estimated value exceeds a predetermined threshold, and the necessity of the transport of the ion beam for cleaning may be determined. In a case where the transport of the high-energy boron ion beam is scheduled after the transport of the low-energy boron ion beam, when the estimated value of the neutron dose rate exceeds a predetermined threshold, the ion beam for cleaning may be transported before the transport of the high-energy boron ion beam.

In the ion implanter 100, the ion implanter 100 may be operated while switching the ion species that is used for the implantation processing in order to suppress the accumulation of a specific element (for example, boron) in the vicinity of the surface of the portion that can serve as a neutron ray generation source. For example, in a case where only the implantation processing using the low-energy boron ion beam is repeatedly executed, the accumulation of boron in the vicinity of the surface of the portion that can serve as a neutron ray generation source is promoted. Thereafter, when the implantation processing using the high-energy boron ion beam is executed, the neutron dose rate is likely to increase. In this case, the implantation processing using an ion beam of an element (for example, arsenic) different from a specific element (for example, boron) is performed after the implantation processing using the low-energy boron ion beam, so that the accumulation of boron in the vicinity of the surface of the portion that can serve as a neutron ray generation source can be suppressed, and an increase in neutron dose rate when the implantation processing using the high-energy boron ion beam is performed can be suppressed.

The processor 50a may acquire a plurality of implantation conditions corresponding to a plurality of lots, and determine a processing order of the plurality of lots by using the acquired plurality of implantation conditions. The processor 50a may acquire, for example, an implantation command including a plurality of implantation conditions from an external management device for managing the operation of the ion implanter 100, and determine a processing order of a plurality of lots, based on the acquired implantation command. The processor 50a may determine a processing order of a plurality of lots such that the accumulation of boron in the vicinity of the surface of the portion that can serve as a neutron ray generation source is suppressed. The processor 50a may execute the implantation processing of implanting the ions into the plurality of wafers included in each of the plurality of lots in the determined processing order in accordance with the corresponding implantation condition.

For example, in a case where the plurality of acquired implantation conditions include a first implantation condition for implanting high-energy boron ions and a second implantation condition for implanting an ion species (for example, arsenic ions) different from the boron ions, the processing order may be determined such that after the plurality of wafers included in the lot of the second implantation condition are implanted with the ion species (for example, arsenic ions) different from the boron ions, the plurality of wafers included in the lot of the first implantation condition are implanted with the high-energy boron ions.

In addition, in a case where the plurality of acquired implantation conditions include a first implantation condition for implanting a high-energy boron ion, a second implantation condition for implanting an ion species (for example, an arsenic ion) different from the boron ion, and a third implantation condition for implanting a low-energy boron ion, the processing order may be determined such that the implantation processing by the first implantation condition is not executed immediately after the implantation processing by the third implantation condition. For example, when the measured value or the estimated value of the neutron dose rate before the start of the implantation processing under the plurality of implantation conditions is equal to or smaller than a predetermined threshold, the implantation processing under the first implantation condition may be first executed, and thereafter, the implantation processing under the second implantation condition and the third implantation condition may be executed. In this case, the implantation processing under the second implantation condition is executed after the implantation processing under the third implantation condition, so that the accumulation of boron in the vicinity of the surface due to the implantation processing under the third implantation condition can be reduced by the implantation processing under the second implantation condition. In a case where the measured value or the estimated value of the neutron dose rate before the start of the implantation processing under to the plurality of implantation conditions exceeds a predetermined threshold, the implantation processing may be executed in the order of the second implantation condition, the first implantation condition, and the third implantation condition. In addition, the implantation processing may be executed in the order of the third implantation condition, the second implantation condition, and the first implantation condition.

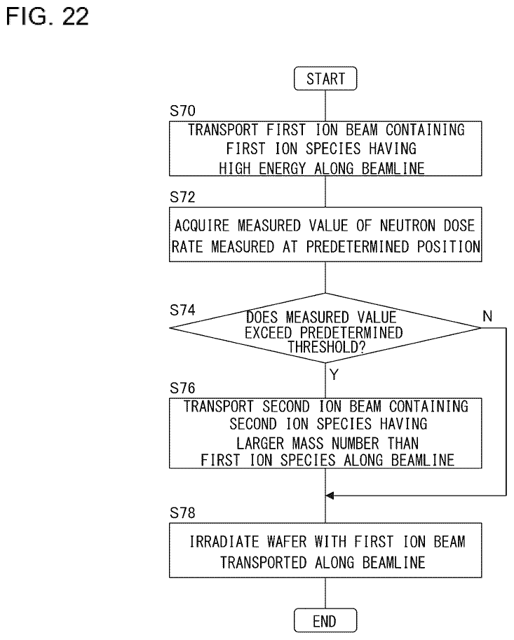

FIG. 22 is a flowchart showing an example of the ion implantation method according to the embodiment. The processor 50a controls the operation of the device main body 58 to transport the first ion beam containing the first ion species having high energy along the beamline BL (S70). Here, an example of the high energy is 3.7 MeV or higher and 10 MeV or lower, and an example of the first ion species is a boron ion. The processor 50a acquires the measured value of the neutron dose rate which is measured at a predetermined position during the transport of the first ion beam (S72). When the measured value exceeds a predetermined threshold (Y in S74), the processor 50a controls the operation of the device main body 58 to stop the transport of the first ion beam and transport the second ion beam containing a second ion species having a larger mass number than the first ion species along the beamline BL (S76). Here, an example of the second ion species is an arsenic ion, and the second ion beam is the ion beam for cleaning described above. The processor 50a transports the first ion beam along the beamline after transport of the second ion beam and irradiates the wafer with the first ion beam to execute the ion implantation processing using the first ion beam (S78). When the measured value is equal to or smaller than the predetermined threshold (N in S74), the processor 50a skips S76 and executes the processing in S78.

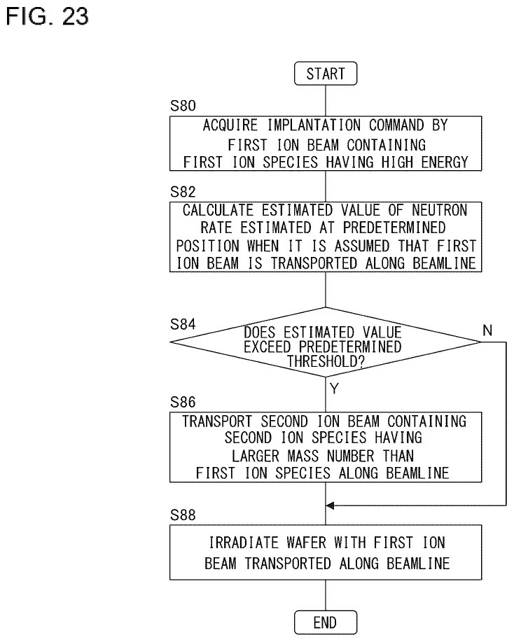

FIG. 23 is a flowchart showing another example of the ion implantation method according to the embodiment. The method shown in FIG. 23 is different from the method shown in FIG. 22 in that a transport necessity of the second ion beam for cleaning is determined using an estimated value instead of a measured value. The processor 50a acquires an implantation command by the first ion beam containing the first ion species having high energy (S80). The implantation command is transmitted to the ion implanter 100 from, for example, an external management device that manages the operation of the ion implanter 100. The processor 50a calculates an estimated value of the neutron dose rate which is estimated at a predetermined position when it is assumed that the first ion beam is transported along the beamline BL (S82). The processor 50a calculates the estimated value of the neutron dose rate by using, for example, the time-series data recorded in the recording device 50c and the beam condition of the first ion beam. When the estimated value exceeds a predetermined threshold (Y in S84), the processor 50a controls the operation of the device main body 58 to transport the second ion beam containing a second ion species having a larger mass number than the first ion species along the beamline BL (S86). The processor 50a transports the first ion beam along the beamline BL after transport of the second ion beam and irradiates the wafer with the first ion beam to execute the ion implantation processing using the first ion beam (S88). When the estimated value is equal to or smaller than a predetermined threshold (N in S84), the processor 50a skips S86 and executes the processing in S88.

In the embodiment described above, a method for calculating the estimated value of the neutron dose rate by using the time-series data of the measured value of the neutron dose rate has been described. In another embodiment, the estimated value of the neutron dose rate may be calculated using time-series data indicating an accumulation state of a specific element (for example, boron) that is accumulated in a portion that can serve as a neutron ray generation source. For example, the accumulation state of a specific element (for example, boron) that is accumulated in a portion that can serve as a neutron ray generation source may be calculated based on the transport results of the ion beam in the beamline BL. Further, the neutron dose rate at a predetermined position may be estimated by using the beam condition of the high-energy ion beam that is incident into the portion where a specific element is accumulated, and the calculated accumulation state of the specific element. The calculation of the accumulation state of the specific element and the estimation of the neutron dose rate may be performed using the techniques described in Japanese Patent No. 6785188 and Japanese Patent No. 6785189 (U.S. Pat. No. 10, 354, 835 and U.S. Pat. No. 10, 490, 389), and the entire contents thereof are incorporated herein by reference.

An aspect of the present embodiment is as follows.

### Aspect 3-1

A method includes: recording time-series data in which a beam condition including an ion species, energy, and a beam current of an ion beam that is transported along a beamline in an ion implanter and a neutron dose rate that is measured at a predetermined measurement position in the ion implanter are associated with each other in a recording device;
transporting a high-energy ion beam along the beamline;
acquiring a measured value of the neutron dose rate that is measured at the predetermined measurement position when transporting the high-energy ion beam;
calculating an estimated value of the neutron dose rate that is estimated at the predetermined measurement position when transporting the high-energy ion beam, by using the time-series data and the beam condition of the high-energy ion beam; and
comparing the measured value with the estimated value.

### Aspect 3-2

In the method according to Aspect 3-1, the ion implanter includes a plurality of operation modes in which the ion beam that is transported along the beamline is at least partially incident into at least one of a plurality of portions in the ion implanter,
the measured value is measured when the high-energy ion beam is transported in at least one of the plurality of operation modes, and
the estimated value is calculated using the neutron dose rate measured when the ion beam is transported in at least one of the plurality of operation modes, in the time-series data.

### Aspect 3-3

In the method according to Aspect 3-2, the ion implanter includes a driving device that changes a position of at least one of the plurality of portions, and
at least one of the plurality of operation modes causes at least one of the plurality of portions to be disposed on the beamline by using the driving device, and causes the ion beam to be at least partially blocked by at least one of the plurality of portions.

### Aspect 3-4

In the method according to Aspect 3-2, the ion implanter includes a deflection device that applies at least one of an electric field and a magnetic field to deflect a trajectory of the ion beam, and
at least one of the plurality of operation modes causes the ion beam to be incident into at least one of the plurality of portions provided away from the beamline by using the deflection device.

### Aspect 3-5

In the method according to any one of Aspects 3-2 to 3-4, the plurality of portions include a first portion, and a second portion located on a downstream side of the beamline with respect to the first portion, and
at least one of the plurality of operation modes causes the ion beam to be at least partially incident into the first portion and causes the ion beam to be at least partially incident into the second portion.

### Aspect 3-6

In the method according to any one of Aspects 3-2 to 3-4, the plurality of portions include a first portion, and a second portion located on a downstream side of the beamline with respect to the first portion,
the plurality of operation modes include a first operation mode in which the ion beam is at least partially incident into the first portion, and a second operation mode in which the ion beam is at least partially incident into the second portion,
the measured value includes a first measured value of the neutron dose rate that is measured at the predetermined measurement position when the high-energy ion beam is transported in the first operation mode, and a second measured value of the neutron dose rate that is measured at the predetermined measurement position when the high-energy ion beam is transported in the second operation mode,
the estimated value includes a first estimated value that is calculated using the neutron dose rate measured when the ion beam is transported in the first operation mode in the time-series data, and a second estimated value that is calculated using the neutron dose rate measured when the ion beam is transported in the second operation mode in the time-series data, and
the comparing includes comparing the first measured value with the first estimated value, and comparing the second measured value with the second estimated value.

### Aspect 3-7

In the method according to any one of Aspects 3-2 to 3-4, the plurality of portions include a first portion, and a second portion located on a downstream side of the beamline with respect to the first portion,
the predetermined measurement position includes a first measurement position and a second measurement position,
the plurality of operation modes include a first operation mode in which the ion beam is at least partially incident into the first portion, and a second operation mode in which the ion beam is at least partially incident into the second portion,
the measured value includes a first measured value of the neutron dose rate that is measured at the first measurement position when the high-energy ion beam is transported in the first operation mode, a second measured value of the neutron dose rate that is measured at the first measurement position when the high-energy ion beam is transported in the second operation mode, a third measured value of the neutron dose rate that is measured at the second measurement position when the high-energy ion beam is transported in the first operation mode, and a fourth measured value of the neutron dose rate that is measured at the second measurement position when the high-energy ion beam is transported in the second operation mode,
the estimated value includes a first estimated value that is calculated using the neutron dose rate measured at the first measurement position when the ion beam is transported in the first operation mode in the time-series data, a second estimated value that is calculated using the neutron dose rate measured at the first measurement position when the ion beam is transported in the second operation mode in the time-series data, a third estimated value that is calculated using the neutron dose rate measured at the second measurement position when the ion beam is transported in the first operation mode in the time-series data, and a fourth estimated value that is calculated using the neutron dose rate measured at the second measurement position when the ion beam is transported in the second operation mode in the time-series data, and
the comparing includes comparing the first measured value with the first estimated value, comparing the second measured value with the second estimated value, comparing the third measured value with the third estimated value, and comparing the fourth measured value with the fourth estimated value.

### Aspect 3-8

In the method according to any one of Aspects 3-1 to 3-5, the predetermined measurement position includes a first measurement position and a second measurement position,
the measured value includes a first measured value of the neutron dose rate that is measured at the first measurement position when the high-energy ion beam is transported, and a second measured value of the neutron dose rate that is measured at the second measurement position when the high-energy ion beam is transported,
the estimated value includes a first estimated value that is calculated using the neutron dose rate that is measured at the first measurement position in the time-series data, and a second estimated value that is calculated using the neutron dose rate that is measured at the second measurement position in the time-series data, and the comparing includes comparing the first measured value with the first estimated value, and comparing the second measured value with the second estimated value.

### Aspect 3-9

In the method according to any one of Aspects 3-1 to 3-8, an ion species of the high-energy ion beam is a boron ion, and energy of the high-energy ion beam is 3.7 MeV or higher and 10 MeV or lower.

### Aspect 3-10

In the method according to any one of Aspects 3-1 to 3-9, the estimated value is calculated using a neutron dose rate corresponding to a beam condition that is the same ion species as the high-energy ion beam and is high energy in a predetermined energy range in the time-series data.

### Aspect 3-11

In the method according to Aspect 3-10, the predetermined energy range is 3.7 MeV or higher and 10 MeV or lower.

### Aspect 3-12

In the method according to Aspect 3-10 or 3-11, the estimated value is calculated using a neutron dose rate corresponding to a beam condition that is the same energy as the high-energy ion beam in the time-series data.

### Aspect 3-13

In the method according to any one of Aspects 3-10 to 3-12, the estimated value is calculated using a neutron dose rate corresponding to a beam condition that is the same beam current as the high-energy ion beam in the time-series data.

### Aspect 3-14

In the method according to any one of Aspects 3-1 to 3-13, the comparing includes determining whether or not a difference between the measured value and the estimated value exceeds a predetermined threshold.

### Aspect 3-15

The method according to Aspect 3-14 further includes: outputting an alert in a case where the difference between the measured value and the estimated value exceeds the predetermined threshold.

### Aspect 3-16

In the method according to Aspect 3-14 or 3-15, the beam condition further include a transport parameter for controlling at least one of a beam central trajectory, a beam size, and a beam shape of the ion beam that is transported along the beamline, and
the method further includes: comparing a transport parameter of the high-energy ion beam with a transport parameter included in the time-series data, in a case where the difference between the measured value and the estimated value exceeds the predetermined threshold.

### Aspect 3-17

In the method according to any one of Aspects 3-1 to 3-16, the ion implanter includes a vacuum chamber that surrounds the beamline and a casing that is disposed outside the vacuum chamber, and
the predetermined measurement position is located outside the vacuum chamber and inside the casing.

### Aspect 3-18

In the method according to any one of Aspects 3-1 to 3-17, the beamline includes a curved portion extending in an arc shape, and
the predetermined measurement position is located inside the curved portion.

### Aspect 3-19

An ion implanter includes:
an ion source that generates an ion beam;
a beamline unit that is configured to transport the ion beam along a beamline and includes an accelerator that accelerates the ion beam to generate a high-energy ion beam;
a neutron ray measuring instrument that is disposed at a predetermined measurement position and measures a neutron dose rate;
a memory in which a program is stored; and
a processor,
in which the processor executes, based on the program,
recording time-series data, in which a beam condition including an ion species, energy, and a beam current of the ion beam that is transported along the beamline and a neutron dose rate that is measured using the neutron ray measuring instrument are associated with each other, in a recording device,
transporting the high-energy ion beam along the beamline,
acquiring a measured value of the neutron dose rate that is measured using the neutron ray measuring instrument when transporting the high-energy ion beam,
calculating an estimated value of the neutron dose rate that is estimated at the predetermined measurement position when transporting the high-energy ion beam, by using the time-series data and the beam condition of the high-energy ion beam, and
comparing the measured value with the estimated value.

Another aspect of the present embodiment is as follows.

### Aspect 4-1

An ion implantation method includes:
acquiring at least one of a first measured value of a neutron dose rate that is measured at a predetermined position in an ion implanter when a first ion beam containing a first ion species with high energy is transported along a beamline in the ion implanter, and a first estimated value of the neutron dose rate that is estimated at the predetermined position when it is assumed that the first ion beam is transported along the beamline;
determining whether or not at least one of the first measured value and the first estimated value exceeds a predetermined threshold;
transporting a second ion beam containing a second ion species having a larger mass number than the first ion species along the beamline in a case where at least one of the first measured value and the first estimated value exceeds the predetermined threshold; and
irradiating a wafer with the first ion beam transported along the beamline, after transport of the second ion beam.

### Aspect 4-2

In the ion implantation method according to Aspect 4-1, the first measured value includes a plurality of first measured values of the neutron dose rate, which are measured at a plurality of predetermined positions in the ion implanter, and the first estimated value includes a plurality of first estimated values of the neutron dose rate, which are estimated at the plurality of predetermined positions, and
in a case where at least one of the plurality of first measured values and the plurality of first estimated values exceeds the predetermined threshold, the second ion beam is transported along the beamline.

### Aspect 4-3

In the ion implantation method according to Aspect 4-1, the ion implanter includes a plurality of operation modes in which an ion beam that is transported along the beamline is at least partially incident into at least one of a plurality of portions in the ion implanter,
the first measured value includes a plurality of first measured values corresponding to the plurality of operation modes, which are measured at the predetermined position when the first ion beam is transported in the plurality of operation modes, and the first estimated value includes a plurality of first estimated values corresponding to the plurality of operation modes, which are estimated at the predetermined position when it is assumed that the first ion beam is transported in the plurality of operation modes, and
the second ion beam is transported along the beamline in a case where at least one of the plurality of first measured values and the plurality of first estimated values exceeds the predetermined threshold.

### Aspect 4-4

In the ion implantation method according to Aspect 4-1, the ion implanter includes a plurality of operation modes in which an ion beam that is transported along the beamline is at least partially incident into at least one of a plurality of portions in the ion implanter,
the first measured value includes a plurality of first measured values, which are measured at a plurality of predetermined positions in the ion implanter when the first ion beam is transported in the plurality of operation modes and corresponding to a combination of the plurality of operation modes and the plurality of predetermined positions, and the first estimated value includes a plurality of first estimated values, which are estimated at the plurality of predetermined positions when it is assumed that the first ion beam is transported in the plurality of operation modes and corresponding to a combination of the plurality of operation modes and the plurality of predetermined positions, and
the second ion beam is transported along the beamline in a case where at least one of the plurality of first measured values and the plurality of first estimated values exceeds the predetermined threshold.

### Aspect 4-5

In the ion implantation method according to Aspect 4-3 or 4-4, the plurality of portions include a first portion, and a second portion located on a downstream side of the beamline with respect to the first portion, and
the plurality of operation modes include a first operation mode in which the ion beam is at least partially incident into the first portion, and a second operation mode in which the ion beam is at least partially incident into the second portion.

### Aspect 4-6

In the ion implantation method according to any one of Aspects 4-3 to 4-5, the ion implanter includes a driving device that changes a position of at least one of the plurality of portions, and
at least one of the plurality of operation modes causes at least one of the plurality of portions to be disposed on the beamline by using the driving device and causes the ion beam to be at least partially blocked by at least one of the plurality of portions.

### Aspect 4-7

In the ion implantation method according to any one of Aspects 4-3 to 4-6, the ion implanter includes a deflection device that applies at least one of an electric field and a magnetic field to deflect a trajectory of the ion beam, and
at least one of the plurality of operation modes causes the ion beam to be incident into at least one of the plurality of portions provided away from the beamline by using the deflection device.

### Aspect 4-8

In the ion implantation method according to any one of Aspects 4-3 to 4-7, the determining includes specifying at least one operation mode corresponding to at least one the first measured value and the first estimated value exceeding the predetermined threshold, and
the transporting of the second ion beam includes transporting the second ion beam in the specified at least one operation mode.

### Aspect 4-9

In the ion implantation method according to any one of Aspects 4-3 to 4-7, the ion implanter includes a plurality of cleaning modes in which a position or a range into which the ion beam is at least partially incident in at least one of the plurality of portions is changed, and
the transporting of the second ion beam includes transporting the second ion beam in at least one of the plurality of cleaning modes.

### Aspect 4-10

In the ion implantation method according to Aspect 4-9, the plurality of portions include a first portion, and a second portion located on a downstream side of the beamline with respect to the first portion, and
the plurality of cleaning modes include a first cleaning mode in which a position or a range into which in the first portion, the ion beam is at least partially incident is changed, and a second cleaning mode in which in the second portion, a position or a range into which the ion beam is at least partially incident is changed.

### Aspect 4-11

In the ion implantation method according to Aspect 4-9 or 4-10, at least one of the plurality of cleaning modes includes changing a transport parameter for controlling at least one of a beam central trajectory, a beam size, and a beam shape of the ion beam.

### Aspect 4-12

In the ion implantation method according to any one of Aspects 4-9 to 4-11, at least one of the plurality of cleaning modes includes changing a position of at least one of the plurality of portions.

### Aspect 4-13

In the ion implantation method according to any one of Aspects 4-9 to 4-12, the transporting the second ion beam includes transporting the second ion beam in at least two of the plurality of cleaning modes.

### Aspect 4-14

In the ion implantation method according to any one of Aspects 4-1 to 4-13, the transporting the second ion beam does not include irradiating the wafer with the second ion beam.

### Aspect 4-15

In the ion implantation method according to any one of Aspects 4-1 to 4-13, the transporting the second ion beam includes irradiating the wafer with the second ion beam.

### Aspect 4-16

In the ion implantation method according to any one of Aspects 4-1 to 4-13, the transporting the second ion beam includes irradiating a plurality of wafers included in at least one lot with the second ion beam.

### Aspect 4-17

In the ion implantation method according to any one of Aspects 4-1 to 4-16, the irradiating a wafer with the first ion beam includes irradiating a plurality of wafers included in at least one lot with the first ion beam.

### Aspect 4-18

In the ion implantation method according to any one of Aspects 4-1 to 4-17, the first ion species is a boron ion, and the high energy is 3.7 MeV or higher and 10 MeV or lower.

### Aspect 4-19

In the ion implantation method according to Aspect 4-18, the second ion species is an ion of phosphorus, arsenic, argon, or fluorine.

### Aspect 4-20

In the ion implantation method according to any one of Aspects 4-1 to 4-19, in a case where at least one of the first measured value and the first estimated value does not exceed the predetermined threshold, the second ion beam is not transported before a wafer is irradiated with the first ion beam that is transported.

### Aspect 4-21

The ion implantation method according to any one of Aspects 4-1 to 4-20 further includes:
acquiring at least one of a second measured value of the neutron dose rate, which is measured at the predetermined position when the first ion beam is transported along the beamline after transport of the second ion beam, and a second estimated value of the neutron dose rate, which is estimated at the predetermined position when it is assumed that the first ion beam is transported along the beamline after transport of the second ion beam;
determining whether or not at least one of the acquired second measured value and second estimated value exceeds the predetermined threshold; and
transporting a third ion beam containing a third ion species having a larger mass number than the first ion species along the beamline before transport of the first ion beam, in case where at least one of the acquired second measured value and second estimated value exceeds the predetermined threshold.

### Aspect 4-22

The ion implantation method according to any one of Aspects 4-1 to 4-21 further includes transporting a fourth ion beam containing the first ion species with low energy along the beamline,
wherein the acquiring of at least one of the first measured value and the first estimated value is performed under a condition in which the first ion beam is transported after transport of the fourth ion beam or a condition in which the first ion beam is scheduled to be transported after transport of the fourth ion beam.

### Aspect 4-23

In the ion implantation method according to Aspect 4-22, the low energy is 0.1 MeV or higher and lower than 3.7 MeV.

### Aspect 4-24

An ion implanter includes:
a first gas supply source that supplies a source gas of a first ion species;
a second gas supply source that supplies a source gas of a second ion species having a larger mass number than the first ion species;
an ion source that generates an ion beam containing the first ion species or the second ion species by using the source gas that is supplied from the first gas supply source or the second gas supply source;
a beamline unit that is configured to transport the ion beam along a beamline and includes an accelerator that accelerates the ion beam;
an implantation processing chamber in which implantation processing of irradiating a wafer with the ion beam transported by the beamline unit is performed;
a memory in which a program is stored; and
a processor,
wherein the processor executes, based on the program,
acquiring at least one of a first measured value of a neutron dose rate that is measured at a predetermined position in the ion implanter when a first ion beam containing the first ion species with high energy is transported along the beamline in the ion implanter, and a first estimated value of the neutron dose rate that is estimated at the predetermined position when it is assumed that the first ion beam is transported along the beamline;
determining whether or not at least one of the first measured value and the first estimated value exceeds a predetermined threshold;
transporting a second ion beam containing the second ion species having a larger mass number than the first ion species along the beamline in a case where at least one of the first measured value and the first estimated value exceeds the predetermined threshold; and
irradiating the wafer with the first ion beam transported along the beamline, after transport of the second ion beam.

### Aspect 4-25

An ion implantation method includes:
acquiring a plurality of implantation conditions corresponding to a plurality of lots;
determining a processing order of the plurality of lots by using the plurality of implantation conditions; and
implanting, in the determined processing order, ions into a plurality of wafers included in each of the plurality of lots according to corresponding implantation conditions,
wherein in a case where the acquired plurality of implantation conditions include a first implantation condition for implanting a first ion species with high energy and a second implantation condition for implanting a second ion species having a larger mass number than the first ion species, a processing order is determined such that the first ion species with high energy is implanted into a plurality of wafers included in a lot of the first implantation condition after the second ion species has been implanted into a plurality of wafers included in a lot of the second implantation condition.

Although the present disclosure has been described above with reference to each of the embodiments described above, the present disclosure is not limited to each of the embodiments described above, and the configuration of each embodiment may be combined as appropriate or may be replaced. Further, it is also possible to appropriately rearrange combinations in each embodiment or processing orders, or to add a modification such as any design change to each embodiment, based on the knowledge of those skilled in the art, and embodiments with such rearrangements or modifications may also be included within the scope of the method, ion implantation, and ion implanter according to the present disclosure.

According to the non-limiting exemplary embodiment of the present invention, it is possible to provide a technique for suppressing an increase in neutron dose rate.

It should be understood that the invention is not limited to the above-described embodiment, but may be modified into various forms on the basis of the spirit of the invention. Additionally, the modifications are included in the scope of the invention.

What is claimed is:

1. An ion implantation method comprising:
acquiring at least one of a first measured value of a neutron dose rate that is measured at a predetermined position in an ion implanter when a first ion beam containing a first ion species with high energy is transported along a beamline in the ion implanter, and a first estimated value of the neutron dose rate that is estimated at the predetermined position when it is assumed that the first ion beam is transported along the beamline;
determining whether or not at least one of the first measured value and the first estimated value exceeds a predetermined threshold;
transporting a second ion beam containing a second ion species having a larger mass number than the first ion species along the beamline in a case where at least one of the first measured value and the first estimated value exceeds the predetermined threshold; and
irradiating a wafer with the first ion beam transported along the beamline, after transport of the second ion beam.

2. The ion implantation method according to claim 1, wherein the first measured value includes a plurality of first measured values of the neutron dose rate, which are measured at a plurality of predetermined positions in the ion implanter, and the first estimated value includes a plurality of first estimated values of the neutron dose rate, which are estimated at the plurality of predetermined positions, and
in a case where at least one of the plurality of first measured values and the plurality of first estimated values exceeds the predetermined threshold, the second ion beam is transported along the beamline.

3. The ion implantation method according to claim 1, wherein the ion implanter includes a plurality of operation modes in which an ion beam that is transported along the beamline is at least partially incident into at least one of a plurality of portions in the ion implanter,
the first measured value includes a plurality of first measured values corresponding to the plurality of operation modes, which are measured at the predetermined position when the first ion beam is transported in the plurality of operation modes, and the first estimated value includes a plurality of first estimated values corresponding to the plurality of operation modes, which are estimated at the predetermined position when it is assumed that the first ion beam is transported in the plurality of operation modes, and
the second ion beam is transported along the beamline in a case where at least one of the plurality of first measured values and the plurality of first estimated values exceeds the predetermined threshold.

4. The ion implantation method according to claim 1, wherein the ion implanter includes a plurality of operation modes in which an ion beam that is transported along the beamline is at least partially incident into at least one of a plurality of portions in the ion implanter,
the first measured value includes a plurality of first measured values, which are measured at a plurality of predetermined portions in the ion implanter when the first ion beam is transported in the plurality of operation modes and corresponding to a combination of the plurality of operation modes and the plurality of predetermined positions, and the first estimated value includes a plurality of first estimated values, which are estimated at the plurality of predetermined positions when it is assumed that the first ion beam is transported in the plurality of operation modes and corresponding to a combination of the plurality of operation modes and the plurality of predetermined positions, and
the second ion beam is transported along the beamline in a case where at least one of the plurality of first measured values and the plurality of first estimated values exceeds the predetermined threshold.

5. The ion implantation method according to claim 3, wherein the plurality of portions include a first portion, and a second portion located on a downstream side of the beamline with respect to the first portion, and
the plurality of operation modes include a first operation mode in which the ion beam is at least partially incident into the first portion, and a second operation mode in which the ion beam is at least partially incident into the second portion.

6. The ion implantation method according to claim 3, wherein the ion implanter includes a driving device that changes a position of at least one of the plurality of portions, and
at least one of the plurality of operation modes causes at least one of the plurality of portions to be disposed on the beamline by using the driving device and causes the ion beam to be at least partially blocked by at least one of the plurality of portions.

7. The ion implantation method according to claim 3, wherein the ion implanter includes a deflection device that applies at least one of an electric field and a magnetic field to deflect a trajectory of the ion beam, and
at least one of the plurality of operation modes causes the ion beam to be incident into at least one of the plurality of portions provided away from the beamline by using the deflection device.

8. The ion implantation method according to claim 3, wherein the determining includes specifying at least one operation mode corresponding to at least one of the first measured value and the first estimated value exceeding the predetermined threshold, and
the transporting of the second ion beam includes transporting the second ion beam in the specified at least one operation mode.

9. The ion implantation method according to claim 3, wherein the ion implanter includes a plurality of cleaning modes in which a position or a range into which the ion beam is at least partially incident in at least one of the plurality of portions is changed, and
the transporting of the second ion beam includes transporting the second ion beam in at least one of the plurality of cleaning modes.

10. The ion implantation method according to claim 9, wherein the plurality of portions include a first portion, and a second portion located on a downstream side of the beamline with respect to the first portion, and
the plurality of cleaning modes include a first cleaning mode in which in the first portion, a position or a range into which the ion beam is at least partially incident is changed, and a second cleaning mode in which in the second portion, a position or a range into which the ion beam is at least partially incident is changed.

11. The ion implantation method according to claim 9, wherein at least one of the plurality of cleaning modes includes changing a transport parameter for controlling at least one of a beam central trajectory, a beam size, and a beam shape of the ion beam.

12. The ion implantation method according to claim 9, wherein at least one of the plurality of cleaning modes includes changing a position of at least one of the plurality of portions.

13. The ion implantation method according to claim 9, wherein the transporting the second ion beam includes transporting the second ion beam in at least two of the plurality of cleaning modes.

14. The ion implantation method according to claim 1, wherein the transporting the second ion beam does not include irradiating the wafer with the second ion beam.

15. The ion implantation method according to claim 1, wherein the transporting the second ion beam includes irradiating the wafer with the second ion beam.

16. The ion implantation method according to claim 1, wherein the transporting the second ion beam includes irradiating a plurality of wafers included in at least one lot with the second ion beam.

17. The ion implantation method according to claim 1, wherein the irradiating a wafer with the first ion beam includes irradiating a plurality of wafers included in at least one lot with the first ion beam.

18. The ion implantation method according to claim 1, wherein the first ion species is a boron ion, and the high energy is 3.7 MeV or higher and 10 MeV or lower.

19. The ion implantation method according to claim 18, wherein the second ion species is an ion of phosphorus, arsenic, argon, or fluorine.

20. The ion implantation method according to claim 1, wherein in a case where at least one of the first measured value and the first estimated value does not exceed the predetermined threshold, the second ion beam is not transported before a wafer is irradiated with the first ion beam that is transported.

21. The ion implantation method according to claim 1, further comprising:
acquiring at least one of a second measured value of the neutron dose rate, which is measured at the predetermined position when the first ion beam is transported along the beamline after transport of the second ion beam, and a second estimated value of the neutron dose rate, which is estimated at the predetermined position when it is assumed that the first ion beam is transported along the beamline after transport of the second ion beam;
determining whether or not at least one of the acquired second measured value and second estimated value exceeds the predetermined threshold; and
transporting a third ion beam containing a third ion species having a larger mass number than the first ion species along the beamline before transport of the first ion beam, in a case where at least one of the acquired second measured value and second estimated value exceeds the predetermined threshold.

22. The ion implantation method according to claim 1, further comprising:
transporting a fourth ion beam containing the first ion species with low energy along the beamline,
wherein the acquiring of at least one of the first measured value and the first estimated value is performed under a condition in which the first ion beam is transported after transport of the fourth ion beam or a condition in which the first ion beam is scheduled to be transported after the transport of the fourth ion beam.

23. The ion implantation method according to claim 22, wherein the low energy is 0.1 MeV or higher and lower than 3.7 MeV.

24. An ion implanter comprising:
a first gas supply source that supplies a source gas of a first ion species;
a second gas supply source that supplies a source gas of a second ion species having a larger mass number than the first ion species;
an ion source that generates an ion beam containing the first ion species or the second ion species by using the source gas that is supplied from the first gas supply source or the second gas supply source;
a beamline unit that is configured to transport the ion beam along a beamline and includes an accelerator that accelerates the ion beam;
an implantation processing chamber wherein implantation processing of irradiating a wafer with the ion beam transported by the beamline unit is performed;
a memory in which a program is stored; and
a processor,
wherein the processor executes, based on the program:
acquiring at least one of a first measured value of a neutron dose rate that is measured at a predetermined position in the ion implanter when a first ion beam containing the first ion species with high energy is transported along the beamline in the ion implanter, and a first estimated value of the neutron dose rate that is estimated at the predetermined position when it is assumed that the first ion beam is transported along the beamline;
determining whether or not at least one of the first measured value and the first estimated value exceeds a predetermined threshold;
transporting a second ion beam containing the second ion species having a larger mass number than the first ion species along the beamline in a case where at least one of the first measured value and the first estimated value exceeds the predetermined threshold; and
irradiating the wafer with the first ion beam transported along the beamline, after transport of the second ion beam.

25. An ion implantation method comprising:
acquiring a plurality of implantation conditions corresponding to a plurality of lots;
determining a processing order of the plurality of lots by using the plurality of implantation conditions; and
implanting, in the determined processing order, ions into a plurality of wafers included in each of the plurality of lots according to corresponding implantation conditions,
wherein in a case where the acquired plurality of implantation conditions include a first implantation condition for implanting a first ion species with high energy and a second implantation condition for implanting a second ion species having a larger mass number than the first ion species, the processing order is determined such that the first ion species with high energy is implanted into a plurality of wafers included in a lot of the first implantation condition after the second ion species has been implanted into a plurality of wafers included in a lot of the second implantation condition.
